(19) United States
(12) Patent Application Publication
(10) Pub. No.: US 2022/0403300 A1
(43) Pub. Date: Dec. 22, 2022

(54) CLEANING LIQUID AND CLEANING METHOD

(71) Applicant: FUJIFILM Corporation, Tokyo (JP)

(72) Inventor: Tetsuya KAMIMURA, Haibara-gun (JP)

(73) Assignee: FUJIFILM Corporation, Tokyo (JP)

(21) Appl. No.: 17/849,027

(22) Filed: Jun. 24, 2022

Related U.S. Application Data
(63) Continuation of application No. PCT/JP2020/043488, filed on Nov. 20, 2020.

(30) Foreign Application Priority Data
Dec. 26, 2019 (JP) 2019-237175
Jul. 6, 2020 (JP) 2020-116075

(51) Int. Cl. C11D 11/00; C11D 3/30; C11D 3/00

(52) U.S. Cl. CPC C11D 11/0047; C11D 3/30; C11D 3/0073

(57) ABSTRACT

There is provided a cleaning liquid excellent in cleaning performance and corrosion prevention performance in application as a cleaning liquid for semiconductor substrates that contain cobalt-containing matter and that have undergone a chemical mechanical polishing process. There is also provided a method of cleaning a semiconductor substrate having undergone a chemical mechanical polishing process. The cleaning liquid is for a semiconductor substrate having undergone a chemical mechanical polishing process, and contains an amine compound Y0 that is at least one selected from the group consisting of: a compound Y1 represented by a general formula (Y1); and a compound Y0 having a 1,4-butanediamine skeleton. The cleaning liquid has a pH of 8.0 to 11.0.

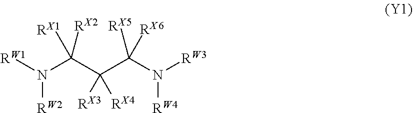

### CROSS-REFERENCE TO RELATED APPLICATIONS

This application is a Continuation of PCT International Application No. PCT/JP2020/043488 filed on Nov. 20, 2020, which claims priority under 35 U.S.C. § 119(a) to Japanese Patent Application No. 2019-237175 filed on Dec. 26, 2019 and Japanese Patent Application No. 2020-116075 filed on Jul. 6, 2020. Each of the above applications is hereby expressly incorporated by reference, in its entirety, into the present application.

### BACKGROUND OF THE INVENTION

The present invention relates to a cleaning liquid for semiconductor substrates and a method of cleaning semiconductor substrates.

Semiconductor devices such as a CCD (Charge-Coupled Device) and a memory are manufactured by forming a fine electronic circuit pattern on a substrate using a photolithography technique. Specifically, a semiconductor device is manufactured by forming a resist film on a laminate including a metal film which is a wiring material, an etching stop layer and an interlayer dielectric layer on a substrate and carrying out a photolithography step and a dry etching step (for instance, plasma etching).

In some cases, a dry etching residue (for instance, metal components such as titanium-based metal derived from a metallic hard mask, or organic components derived from a photoresist film) remains on a substrate having undergone the dry etching step.

In manufacture of semiconductor devices, a chemical mechanical polishing (CMP) process is sometimes carried out to planarize a surface of a substrate having a metal wiring film, a barrier metal, an insulating film and the like by use of an abrasive slurry containing fine abrasive particles (for instance, silica, alumina). In the CMP process, metal components derived from the fine abrasive particles used in the CMP process and from the metal wiring film and/or the barrier metal having been polished tend to remain on the surface of the semiconductor substrate after polishing.

Since those residues may cause a short-circuit between wires and affect electrical properties of a semiconductor, it is common practice to carry out a cleaning step for removing the residues from the surface of the semiconductor substrate.

For instance, JP 2018-507540 A describes: “A composition comprising: (a) one or more quaternary ammonium hydroxides in an amount effective to regulate the pH of the composition to a pH of from about 10 to about 14, (b) one or more organic amines, (c) one or more metal inhibitors selected from purines, azoles, pyrimidines, thiazoles, thiazolinones, polyphenols, barbituric acid derivatives, Schiff bases, and combinations thereof, and (d) water, wherein the composition is suited for removing contaminants from semiconductor wafers following chemical-mechanical polishing” (claim 1).

### SUMMARY OF THE INVENTION

The present inventors studied a cleaning liquid for semiconductor substrates having undergone CMP by reference to, for instance, JP 2018-507540 A. As a result, the present inventors have obtained a knowledge about semiconductor substrates including metal films containing cobalt. Specifically, the present inventors have found that it is difficult for a cleaning liquid to have cleaning performance and corrosion prevention performance at the same time with respect to semiconductor substrates having undergone CMP.

An object of the present invention is to provide a cleaning liquid excellent in cleaning performance and corrosion prevention performance when the cleaning liquid is applied as a cleaning liquid for semiconductor substrates that have cobalt-containing matter and that have undergone CMP. Another object of the present invention is to provide a method of cleaning semiconductor substrates having undergone CMP.

The present inventor found that the above objects can be attained with the following configuration.
[1] A cleaning liquid for a semiconductor substrate having undergone a chemical mechanical polishing process, the cleaning liquid comprising:

an amine compound Y0 that is at least one selected from the group consisting of: a compound Y1 represented by a general formula (Y1); and a compound Y2 having a 1,4-butanediamine skeleton,

wherein the cleaning liquid has a pH of 8.0 to 11.0,

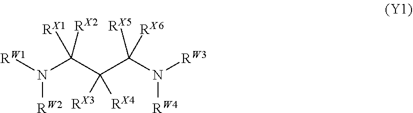

where R^{W1} to R^{W4} and R^{X1} to R^{X6} each independently represent a hydrogen atom or a hydrocarbon group that may have a substituent;

R^{W1} and R^{W2} may be bonded to R^{X1} to R^{X6} to form a ring;

R^{W3} and R^{W4} may be bonded to R^{X1} to R^{X6} to form a ring;

two groups selected from R^{X1} to R^{X6} may be bonded to each other to form a ring;

R^{W1} and R^{W2} may be bonded to each other to form a ring having, as its ring member atoms, only atoms selected from the group consisting of a carbon atom and a nitrogen atom; and

R^{W3} and R^{W4} may be bonded to each other to form a ring having, as its ring member atoms, only atoms selected from the group consisting of a carbon atom and a nitrogen atom,

provided that the general formula (Y1) satisfies at least one of a requirement A and a requirement B, the requirement A being that at least one of R^{W1} to R^{W4} represents a group other than a hydrogen atom, the requirement B being that at least two of R^{X1} to R^{X6} each represent a group other than a hydrogen atom.
[2] The cleaning liquid according to [1], wherein the amine compound Y0 is at least one compound selected from the group consisting of 1,4-butandiamine, 2,2-dimethyl-1,3-propanediamine, N,N-dimethyl-1,3-propanediamine, N-methyl-1,3-diaminopropane, 3,3′-diamino-N-methyldipropylamine, 3,3′-diaminodipropylamine, N,N-diethyl-1,3-diaminopropane, N,N,2,2-tetramethyl-1,3-propanediamine, 3-(dibutylamino)propylamine, N,N,N′,N′-tetramethyl-1,3-diaminopropane, N,N′-bis(3-aminopropyl)ethylenediamine, 2,6,10-trimethyl-2,6,10-triazaundecan, N-(3-aminopropyl)diethanolamine, N-(3-aminopropyl)cyclohexylamine, 1,4-bis(3-aminopropyl)piperidine, 1-(3-aminopropyl)-2-methylpiperidine, 4-aminopiperidine, 4-amino-2,2,6,6-tetramethylpiperidine, 1,3-propanediamine-N,N,N′,N′-tetraacetic acid, 1-(3-aminopropyl)imidazole, N3-amine3-(2-aminoethylamino)propylamine, and N4-amine-N,N′-bis(3-aminopropyl)ethylenediamine.
[3] The cleaning liquid according to [1] or [2], wherein the cleaning liquid further contains an amine compound Z different from the amine compound Y0.
[4] The cleaning liquid according to [3], wherein a mass ratio of a content of the amine compound Z to a content of the amine compound Y0 is 2 to 100.
[5] The cleaning liquid according to [4], wherein the amine compound Z comprises two or more amine compounds Z, and the cleaning liquid contains the two or more amine compounds Z.
[6] The cleaning liquid according to any one of [1] to [5], wherein a content of the amine compound Y0 is 1.0 to 30 mass % based on a total mass of components, excluding solvent, contained in the cleaning liquid.
[7] The cleaning liquid according to any one of [1] to [6], wherein the amine compound Y0 comprises two or more amine compounds Y0, and the cleaning liquid contains the two or more amine compounds Y0.
[8] The cleaning liquid according to any one of [1] to [7], wherein the cleaning liquid further contains an anticorrosive.
[9] The cleaning liquid according to [8], wherein the anticorrosive includes a reducing agent.
[10] The cleaning liquid according to [8] or [9], wherein the anticorrosive includes one or both of a reducing sulfur compound and a hydroxycarboxylic acid.
[11] The cleaning liquid according to [10], wherein a mass ratio of a content of the amine compound Y0 to a total content of the reducing sulfur compound and the hydroxycarboxylic acid is 0.3 to 1.5.
[12] The cleaning liquid according to any one of [8] to [11], wherein the anticorrosive includes one or both of an azole compound and a biguanide compound.
[13] The cleaning liquid according to [12], wherein the anticorrosive includes both the azole compound and the biguanide compound.
[14] The cleaning liquid according to any one of [1] to [13], wherein the semiconductor substrate has a metal film containing cobalt.
[15] A method of cleaning a semiconductor substrate, the method comprising a step of applying the cleaning liquid according to any one of [1] to [14] to the semiconductor substrate having undergone a chemical mechanical polishing process.

The present invention provides a cleaning liquid excellent in cleaning performance and corrosion prevention performance when the cleaning liquid is applied as a cleaning liquid for semiconductor substrates that have cobalt-containing matter and that have undergone CMP. The present invention also provides a method of cleaning semiconductor substrates having undergone CMP.

### DETAILED DESCRIPTION OF THE INVENTION

One exemplary embodiment of the invention is described below.

In this specification, a numerical range expressed in the form of “A to B” should read as a range including both the values A and B as the range's lower and upper limits, respectively.

In this specification, when a certain component comprising two or more types is present, the “content” of the certain component means the total content of the two or more types.

In this specification, “ppm” means “parts per million (10⁻⁶)”, and “ppb” means “parts per billion (10⁻⁹)”.

In compounds described in this specification, isomers (compounds with the same number of atoms but different structures), optical isomers, and isotopes may be included unless particularly limited. As isomers and isotopes, only one type or plural types may be included.

In this specification, “psi” refers to “pound-force per square inch”, and 1 psi=6894.76 Pa.

A cleaning liquid of the present invention (hereinafter also simply called “cleaning liquid”) is a cleaning liquid for semiconductor substrates having undergone a chemical mechanical polishing (CMP) process. The cleaning liquid contains one or more amine compounds Y0 selected from the group consisting of a compound Y1 and a compound Y2. The compound Y1 is represented by a general formula (Y1), described below. The compound Y2 has a 1,4-butanediamine skeleton. The cleaning liquid has a pH of 8.0 to 11.0.

While it is not clear how this configuration attains the above objects, the present inventors presume the following mechanism as a possible explanation.

It is presumed that the compound Y2, which has a 1,4-butanediamine skeleton, has excellent reactivity with respect to cobalt, excellent cleaning properties, and excellent corrosion prevention properties.

Also, the compound Y1 corresponds to a compound having a 1,3-propanediamine skeleton having a predetermined structure. The compound Y1 satisfies at least one of a requirement A and a requirement B. The requirement A is to have at least one group other than a hydrogen atom on the nitrogen atom at each of the two ends of the 1,3-propanediamine skeleton. The requirement B is to have at least two groups other than a hydrogen atom on the alkylene chain of the 1,3-propanediamine skeleton. It is presumed that such compound Y1 causes an appropriate level of steric hindrance to occur when the compound Y1 reacts with a metal component, eliminating or minimizing surface corrosion caused by excessive reaction with a metal component such as cobalt. It is also presumed that such compound Y1 has an appropriately adjusted range of hydrophobic property throughout the compound Y1, eliminating or minimizing generation of residues containing the compound Y1.

The cleaning liquid according to this embodiment of the present invention is also excellent in cleaning performance and corrosion prevention performance with respect to metal films containing copper and/or tungsten.

When one cleaning liquid is greater in excellence than another cleaning liquid in at least one of cleaning performance and corrosion prevention performance for a metal film containing cobalt, copper, and/or tungsten, the one cleaning liquid will be occasionally referred to as having greater excellence in the effectiveness of the present invention.

### [Cleaning Liquid]

Each component contained in the cleaning liquid is described below.

### [Amine Compound Y0]

The cleaning liquid contains one or more amine compounds Y0 selected from the group consisting of: the compound Y1, which is represented by the general formula (Y1); and the compound Y2, which has a 1,4-butanediamine skeleton.

### <Compound Y1>

The compound Y1 is a compound represented by the general formula (Y1).

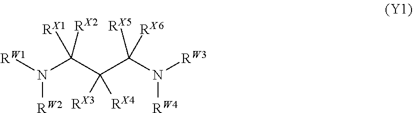

In the general formula (Y1), R^{W1} to R^{W4} and R^{X1} to R^{X6} each independently represent a hydrogen atom or a hydrocarbon group that may have a substituent.

Examples of the hydrocarbon group that may have a substituent include an alkyl group. Each alkyl group may be linear or branched, and may be partially or entirely cyclic.

The number of carbon atoms of the alkyl group is preferably 1 to 10, more preferably 1 to 6, and still more preferably 1 to 4.

Examples of the substituent that the hydrocarbon group (preferably alkyl group) may have include a carboxy group, a hydroxyl group, and —NR^{P}₂.

The two R^{P}s in —NR^{P}₂ each independently represent a hydrogen atom or an alkyl group that may have a substituent.

The alkyl group that is represented by R^{P} and that may have a substituent may be linear or branched, and may be partially or entirely cyclic. The number of carbon atoms is preferably 1 to 10, more preferably 1 to 6, and still more preferably 1 to 4.

Examples of the substituent that the alkyl group represented by R^{P} may have include a carboxy group, a hydroxyl group, and —NR^{Q}₂.

The two R^{Q}s in —NR^{Q}₂ each independently represent a hydrogen atom or an alkyl group (which may be linear or branched, and may be partially or entirely cyclic; and the number of carbon atoms is preferably 1 to 10, more preferably 1 to 6, and still more preferably 1 to 4).

The total carbon number of the hydrocarbon group that may have a substituent is preferably 1 to 20, more preferably 1 to 10, and still more preferably 1 to 6.

Examples of the hydrocarbon group that may have a substituent include an alkyl group, a hydroxyalkyl group, a carboxyalkyl group, an aminoalkyl group, an alkylaminoalkyl group, a dialkylaminoalkyl group, and an aminoalkylaminoalkyl group.

R^{W1} and R^{W2} may be bonded to R^{X1} to R^{X6} to form a ring. In a case of forming a ring, it is preferable to bond one of R^{W1} and R^{W2} to one of R^{X1} to R^{X6} (preferably R^{X5} or R^{X 6}) to form a ring.

R^{W3} and R^{W4} may be bonded to R^{X1} to R^{X6} to form a ring. In a case of forming a ring, it is preferable to bond one of R^{W3} and R^{W4} to one of R^{X1} to R^{X6} (preferably R^{X1} or R^{X2}) to form a ring.

Two groups selected from R^{X1} to R^{X6} may be bonded to each other to form a ring. In a case of forming a ring, only one combination of two groups selected from R^{X1} to R^{X6} may be present, or two or more such combinations may be present at the same time.

R^{W1} and R^{W2} may be bonded to each other to form a ring having, as its ring member atoms, only atoms selected from the group consisting of a carbon atom and a nitrogen atom.

R^{W3} and R^{W4} may be bonded to each other to form a ring having, as its ring member atoms, only atoms selected from the group consisting of a carbon atom and a nitrogen atom.

When a ring is formed by bonding of R^{W1} and R^{W2} with R^{X1} to R^{X6}, R^{W3} and R^{W4} with R^{X1} to R^{X6}, and/or two groups selected from R^{X1} to R^{X6}, the ring may be monocyclic or polycyclic. Further, the ring may have a substituent. The number of ring member atoms of the ring is preferably 3 to 20, more preferably 4 to 10, and still more preferably 5 or 6. The ring member atoms of the ring are preferably a carbon atom(s) and/or a nitrogen atom(s). The number of nitrogen atoms included in the ring member atoms of the ring is preferably 0 to 4, and more preferably 0 to 2.

Preferably, a total number of rings formed by bonding of R^{W1} and R^{W2} with R^{X1} to R^{X6}, R^{W3} and R^{W4} with R^{X1} to R^{X6}, and/or two groups selected from R^{X1} to R^{X6} is 0 or 1.

When R^{W1} and R^{W2} are bonded to each other to form a ring and/or when R^{W3} and R^{W4} are bonded to each other to form a ring, the ring may be monocyclic or polycyclic. The ring may be an aromatic ring or a non-aromatic ring. Further, the ring may have a substituent. The number of ring member atoms of the ring is preferably 3 to 20, more preferably 4 to 10, and still more preferably 5 or 6. The ring member atoms of the ring are a carbon atom(s) and/or a nitrogen atom(s). The number of nitrogen atoms included in the ring member atoms of the ring is preferably 1 to 4, and more preferably 1 or 2.

It should be noted that the ring member atoms of the ring formed by bonding of R^{W1} and R^{W2} and the ring member atoms of the ring formed by bonding of R^{W3} and R^{W4} do not include atoms (such as an oxygen atom) other than atoms selected from the group consisting of a carbon atom and a nitrogen atom. If a hetero atom other than a nitrogen atom is included as a ring member atom of a ring having a limited degree of freedom, such a hetero atom may inhibit an interaction of the amino group with cobalt, deteriorating cobalt removability. It is believed, as a result, that a desired effect is not obtained.

A substituent may be included in the ring formed by bonding of R^{W1} and R^{W2} with R^{X1} to R^{X6}, the ring formed by bonding of R^{W3} and R^{W4} with R^{X1} to R^{X6}, the ring formed by bonding of two groups selected from R^{X1} to R^{X6}, the ring formed by bonding of R^{W1} and R^{W2}, and/or the ring formed by bonding of R^{W3} and R^{W4}. Examples of such a substituent include alkyl groups, hydroxyalkyl groups, carboxyalkyl groups, aminoalkyl groups, alkylaminoalkyl groups, dialkylaminoalkyl groups, and aminoalkylaminoalkyl groups.

It should be noted that the general formula (Y1) satisfies at least one of the requirement A and the requirement B.

Requirement A: At least one (that is, 1 to 4) of R^{W1} to R^{W4} represents a group other than a hydrogen atom.

Requirement B: At least two (that is, 2 to 6, and preferably 2 to 4) of R^{X1} to R^{X6} each represent a group other than a hydrogen atom.

As used herein, the “group other than a hydrogen atom” is: the above-described hydrocarbon group that may have a substituent; or a group contributing to formation of a ring when the ring is formed by bonding of groups (R^{W1} and R^{W2} with R^{X1} to R^{X6}; R^{W3} and R^{W4} with R^{X1} to R^{X 6}; two groups selected from R^{X1} to R^{X6}; R^{W1} and R^{W2}; and R^{W3} and R^{W4})

The compounds Y1 may be used singly or in combination of two or more.

### <Compound Y2>

The compound Y2 is a compound having a 1,4-butanediamine skeleton.

It should be noted, however, that the compound Y2 is preferably a compound other than the compound Y1.

The compound Y2 is preferably a compound represented by, for instance, a general formula (Y2).

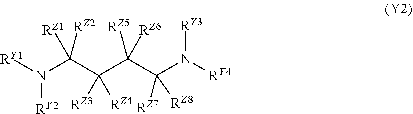

In the general formula (Y2), R^{Y1} to R^{Y4} and R^{Z1} to R^{Z8} each independently represent a hydrogen atom or a hydrocarbon group that may have a substituent.

Examples of the hydrocarbon group that may have a substituent include the hydrocarbon group that may have a substituent as described for the general formula (Y1).

R^{Y1} and R^{Y2} may be bonded to each other to form a ring.
R^{Y3} and R^{Y4} may be bonded to each other to form a ring.
R^{Y1} and R^{Y2} may be bonded to R^{Y3} and R^{Y4} to form a ring.
R^{Y1} and R^{Y2} may be bonded to R^{Z1} to R^{Z8} to form a ring. In a case of forming a ring, it is preferable to bond one of R^{Y1} and R^{Y2} to one of R^{Z1} to R^{Z8} to form a ring.

R^{Y3} and R^{Y4} may be bonded to R^{Z1} to R^{Z8} to form a ring. In a case of forming a ring, it is preferable to bond one of R^{Y3} and R^{Y4} to one of R^{Z1} to R^{Z8} to form a ring.

Two groups selected from R^{Z1} to R^{Z8} may be bonded to each other to form a ring.

In a case where these rings are formed, examples of these rings include the rings that are formed by bonding groups to each other as described for the general formula (Y1).

In a case where the above-described rings are formed, examples of a ring formed by bonding groups to each other include rings that are formed by bonding groups to each other as described for the general formula (Y1).

The compounds Y2 may be used singly or in combination of two or more.

The amine compound Y0 is preferably one or more compounds selected from the group consisting of 1,4-butandiamine, 2,2-dimethyl-1,3-propanediamine, N,N-dimethyl-1,3-propanediamine, N-methyl-1,3-diaminopropane, 3,3′-diamino-N-methyldipropylamine, 3,3′-diaminodipropylamine, N,N-diethyl-1,3-diaminopropane, N,N,2,2-tetramethyl-1,3-propanediamine, 3-(dibutylamino)propylamine, N,N,N′,N′-tetramethyl-1,3-diaminopropane, N,N′-bis(3-aminopropyl)ethylenediamine, 2,6,10-trimethyl-2,6,10-triazaundecan, N-(3-aminopropyl)diethanolamine, N-(3-aminopropyl)cyclohexylamine, 1,4-bis(3-aminopropyl)piperidine, 1-(3-aminopropyl)-2-methylpiperidine, 4-aminopiperidine, 4-amino-2,2,6,6-tetramethylpiperidine, 1,3-propanediamine-N,N,N′,N′-tetraacetic acid, 1-(3-aminopropyl)imidazole, N3-amine3-(2-aminoethylamino)propylamine, and N4-amine-N,N′-bis(3-aminopropyl)ethylenediamine.

The molecular weight of the amine compound Y0 (the compound Y1 or the compound Y2) is preferably 88 to 600, more preferably 88 to 500, and still more preferably 88 to 400.

The total number of amino groups (preferably the total number of primary amino groups, secondary amino groups, and tertiary amino groups) that the amine compound Y0 (the compound Y1 or the compound Y2) has in its molecule is preferably 2 to 10, more preferably 2 to 6, and still more preferably 2 to 4.

The amine compounds Y0 may be used singly or in combination of two or more.

When two or more amine compounds Y0 are used, the cleaning performance for metal (for instance, Co, W, and Cu) is greater in excellence.

When two or more amine compounds Y0 are contained, it is assumed that a first amine compound Y0 of the two or more amine compounds Y0 has the highest content, and a second amine compound Y0 of the two or more amine compounds Y0 has the second highest content. In this case, the mass ratio of the content of the second amine compound Y0 to the content of the first amine compound Y0 (the content of the second amine compound Y0/the content of the first amine compound Y0) is preferably 0.01 to 1, more preferably 0.1 to 1, and still more preferably 0.4 to 1. It should be noted that the content of the first amine compound Y0 may be substantially the same as the content of the second amine compound Y0.

In view of excellence in residue removability and in view of greater excellence in cleaning performance, the content of the amine compound Y0 (preferably the compound Y1) is preferably not less than 0.001 mass %, more preferably not less than 0.02 mass %, still more preferably more than 0.05 mass %, particularly preferably not less than 0.1 mass %, and most preferably not less than 5 mass % based on the total mass of the cleaning liquid.

In view of excellence in corrosion prevention performance for metal (for instance, Co, W, and Cu), the content of the amine compound Y0 (preferably the compound Y1) is preferably not more than 20 mass %, more preferably not more than 15 mass %, still more preferably not more than 5 mass %, and particularly preferably less than 5 mass % based on the total mass of the cleaning liquid.

In view of excellence in keeping a good balance between performances, the content of the amine compound Y0 (preferably the compound Y1) is preferably 0.001 to 20 mass %, more preferably 0.05 to 20 mass %, still more preferably more than 0.05 mass % and not more than 15 mass %, particularly preferably more than 0.05 mass % and not more than 10 mass %, and most preferably more than 0.05 mass % and less than 5 mass % based on the total mass of the cleaning liquid.

In view of excellence in residue removability and in view of greater excellence in cleaning performance, the content of the amine compound Y0 (preferably the compound Y1) is preferably not less than 0.05 mass %, more preferably not less than 0.4 mass %, still more preferably not less than 0.7 mass %, particularly preferably not less than 1.0 mass %, and most preferably not less than 30 mass % based on the total mass of the components, excluding solvent, contained in the cleaning liquid.

In view of excellence in corrosion prevention performance for metal (for instance, Co, W, and Cu), the content of the amine compound Y0 (preferably the compound Y1) is preferably not more than 75 mass %, more preferably not more than 65 mass %, still more preferably not more than 35 mass %, and particularly preferably not more than 30 mass % based on the total mass of the components, excluding solvent, contained in the cleaning liquid.

In view of excellence in keeping a good balance between performances, the content of the amine compound Y0 (preferably the compound Y1) is preferably 0.05 to 75 mass %, more preferably 0.4 to 75 mass %, still more preferably 1.0 to 65 mass %, particularly preferably 1.0 to 35 mass %, and most preferably 1.0 to 30 mass % based on the total mass of the components, excluding solvent, contained in the cleaning liquid.

As used herein, the “total mass of the components, excluding solvent, contained in the cleaning liquid” means the total of the contents of all the components of the cleaning liquid other than water and organic solvent.

### [Water]

The cleaning liquid preferably contains water as a solvent. The type of water used in the cleaning liquid is not particularly limited as long as it has no bad influence on a semiconductor substrate, and distilled water, deionized water, and pure water (ultrapure water) are usable. Pure water is preferred because it hardly contains impurities and its influence on a semiconductor substrate is smaller in a semiconductor substrate manufacturing process.

The water content of the cleaning liquid may be the remainder of the optional components described below. For instance, the water content is preferably not less than 1 mass %, more preferably not less than 30 mass %, still more preferably not less than 60 mass %, and particularly preferably not less than 85 mass % based on the total mass of the cleaning liquid. While the upper limit of the water content is not particularly limited, the upper limit is preferably not more than 99.99 mass %, more preferably not more than 99.95 mass %, still more preferably not more than 99 mass %, and particularly preferably not more than 95 mass % based on the total mass of the cleaning liquid.

### [Amine Compound Z]

The cleaning liquid may further contain an amine compound Z. The amine compound Z is different from the amine compound Y0.

The amine compound Z may be: a primary amine having in its molecule a primary amino group (—NH₂); a secondary amine having in its molecule a secondary amino group (>NH); a tertiary amine having in its molecule a tertiary amino group (>N—); a quaternary ammonium compound having a quaternary ammonium cation; or salts thereof. The amine compound Z may also be a compound satisfying plural requirements out of the foregoing requirements.

It should be noted, however, that the amine compound Z is a compound that does not correspond to the amine compound Y0.

It should also be noted that the amine compound Z does not include a hydroxylamine compound, an aminocarboxylic acid, a nitrogen-containing heteroaromatic compound (such as an azole compound), and a biguanide compound.

### <Primary Amine, Secondary Amine, and Tertiary Amine>

The cleaning liquid may contain, as the amine compound Z, at least one selected from the group consisting of a primary amine, a secondary amine, and a tertiary amine (hereinafter also referred to as “primary to tertiary amines”).

In view of greater excellence in defect suppression performance, the cleaning liquid preferably contains primary to tertiary amines.

Examples of the primary to tertiary amines include an amino alcohol, an amine compound having a cyclic structure, and a monoamine or polyamine other than the foregoing amines.

Examples of the salts of the primary to tertiary amines include a salt of an inorganic acid in which at least one non-metal selected from the group consisting of Cl, S, N, and P is bonded to hydrogen. Preferable salt examples include hydrochloride, sulfate, and nitrate.

### (Amino Alcohol)

The amino alcohol is a compound that is among the primary to tertiary amines and that further has in its molecule at least one hydroxylalkyl group. While the amino alcohol may have any of primary to tertiary amino groups, the amino alcohol preferably has a primary amino group.

Examples of the amino alcohol include monoethanolamine (MEA), 2-amino-2-methyl-1-propanol (AMP), diethanolamine (DEA), triethanolamine (TEA), diethylene glycol amine (DEGA), tris(hydroxymethyl)aminomethane (Tris), 2-(methylamino)-2-methyl-1-propanol (N-MAMP), dimethylbis(2-hydroxyethyl)ammonium hydroxide (AH212), 2-(2-aminoethylamino)ethanol (AAE), and 2-(aminoethoxy) ethanol (AEE).

In particular, MEA, AMP, DEA, AEE, AAE, or N-MAMP is preferred, and MEA, AMP, or AEE is more preferred.

When the cleaning liquid contains the amino alcohol, the content of the amino alcohol is preferably 0.5 to 20 mass %, more preferably 1 to 15 mass %, and still more preferably 2 to 10 mass % based on the total mass of the cleaning liquid.

When the cleaning liquid contains the amino alcohol, the content of the amino alcohol is preferably 10 to 98 mass %, more preferably 30 to 90 mass %, and still more preferably 45 to 85 mass % based on the total mass of the components, excluding solvent, contained in the cleaning liquid.

(Amine Compound having Cyclic Structure)

Of an amine compound having a cyclic structure, the cyclic structure is not particularly limited, and examples thereof include a heterocyclic ring in which at least one of atoms constituting the ring is a nitrogen atom (nitrogen-containing heterocyclic ring).

Examples of the amine compound having a cyclic structure include a pyridine compound, a pyrazine compound, a pyrimidine compound, a piperazine compound, and a cyclic amidine compound.

The pyridine compound is a compound having a six-membered heterocyclic ring (pyridine ring) containing one nitrogen atom and having aromatic properties.

Specific examples of the pyridine compound include pyridine, 3-aminopyridine, 4-aminopyridine, 3-hydroxypyridine, 4-hydroxypyridine, 2-acetamidopyridine, 2-cyanopyridine, 2-carboxypyridine, and 4-carboxypyridine.

The pyrazine compound is a compound having a six-membered heterocyclic ring (pyrazine ring) containing two nitrogen atoms at the para positions and having aromatic properties. The pyrimidine compound is a compound having a six-membered heterocyclic ring (pyrimidine ring) containing two nitrogen atoms at the meta positions and having aromatic properties.

Examples of the pyrazine compound include pyrazine, 2-methylpyrazine, 2,5-dimethylpyrazine, 2,3,5-trimethylpyrazine, 2,3,5,6-tetramethylpyrazine, 2-ethyl-3-methylpyrazine, and 2-amino-5-methylpyrazine, with pyrazine being preferred.

Examples of the pyrimidine compound include pyrimidine, 2-methylpyrimidine, 2-aminopyrimidine, and 4,6-dimethylpyrimidine, with 2-aminopyrimidine being preferred.

The piperazine compound is a compound having a six-membered heterocyclic ring (piperazine ring) in which opposed —CH— groups in a cyclohexane ring are substituted with nitrogen atoms. The piperazine compound is favorable because it leads to greater excellence in the effectiveness of the present invention.

The piperazine compound may have a substituent on the piperazine ring. Examples of the substituent include a hydroxy group, an alkyl group having 1 to 4 carbon atoms that may have a hydroxy group, and an aryl group having 6 to 10 carbon atoms.

Examples of the piperazine compound include piperazine, 1-methylpiperazine, 1-ethylpiperazine, 1-propylpiperazine, 1-butylpiperazine, 2-methylpiperazine, 1,4-dimethylpiperazine, 2,5-dimethylpiperazine, 2,6-dimethylpiperazine, 1-phenylpiperazine, 2-hydroxypiperazine, 2-hydroxymethylpiperazine, 1-(2-hydroxyethyl)piperazine (HEP), N-(2-aminoethyl)piperazine (AEP), 1,4-bis(2-hydroxyethyl)piperazine (BHEP), 1,4-bis(2-aminoethyl)piperazine (BAEP), and 1,4-bis(3-aminopropyl)piperazine (BAPP), with preferred being piperazine, 1-methylpiperazine, 2-methylpiperazine, HEP, AEP, BHEP, BAEP, or BAPP, and more preferred being HEP, AEP, BHEP, BAEP, or BAPP.

The cyclic amidine compound is a compound having a heterocyclic ring including an amidine structure (>N—C═N—) in the ring.

The number of atoms constituting the heterocyclic ring of the cyclic amidine compound is not particularly limited and is preferably five or six and more preferably six.

Examples of the cyclic amidine compound include diazabicycloundecene (1,8-diazabicyclo[5.4.0]undec-7-ene: DBU), diazabicyclononene (1,5-diazabicyclo[4.3.0]non-5-ene: DBN), 3,4,6,7,8,9,10,11-octahydro-2H-pyrimido[1.2-a]azocine, 3,4,6,7,8,9-hexahydro-2H-pyrido[1.2-a]pyrimidine, 2,5,6,7-terahydro-3H-pyrrolo[1.2-a]imidazole, 3-ethyl-2,3,4,6,7,8,9,10-octahydropyrimido[1.2-a]azepine, and creatinine, with DBU or DBN being preferred.

Examples of the amine compound having a cyclic structure include, in addition to the foregoing examples, a compound having a five-membered heterocyclic ring with no aromatic properties such as 1,3-dimethyl-2-imidazolidinone or imidazolidinethione, and a compound having a seven-membered ring containing a nitrogen atom(s).

For the amine compound having a cyclic structure, preferred is a piperazine compound or a cyclic amidine compound, and more preferred is a piperazine compound.

### (Monoamine Compound)

The monoamine compound other than the amino alcohol and the amine compound having a cyclic structure is not particularly limited, and examples thereof include a compound represented by Formula (a) (hereinafter also referred to as “compound (a)”):

NHₓR₍₃₋ₓ₎ (a)

where R represents an alkyl group having 1 to 3 carbon atoms, and x represents an integer of 0 to 2.

Examples of the alkyl group having 1 to 3 carbon atoms include a methyl group, an ethyl group, an n-propyl group, and an isopropyl group, with an ethyl group or an n-propyl group being preferred.

Examples of the compound (a) include methylamine, ethylamine, propylamine, dimethylamine, diethylamine, trimethylamine, and triethylamine, with preferred being ethylamine, propylamine, diethylamine, or triethylamine.

When the cleaning liquid contains two or more amine compounds and at least one of the two or more amine compounds is the compound (a), this leads to excellent defect suppression performance for a metal film (particularly Cu- or Co-containing film) and is therefore favorable. While not bound by any theory, the reason for the above is believed to be that the component (a) is a low molecular compound, has a relatively high water solubility, and has excellent speed of coordination to metal (for instance, Co, W and Cu).

Examples of the monoamine compound other than the compound (a) include benzylamine, diethylamine, n-butylamine, 3-methoxypropylamine, tert-butylamine, n-hexylamine, cyclohexylamine, n-octylamine, and 2-ethylhexylamine.

When the cleaning liquid contains the monoamine compound, the content of the monoamine compound is preferably 0.0001 to 10.0 mass % and more preferably 0.001 to 5.00 mass % based on the total mass of the cleaning liquid.

When the cleaning liquid contains the monoamine compound, the content of the monoamine compound is preferably 0.001 to 98 mass % and more preferably 0.03% to 90 mass % based on the total mass of the components, excluding solvent, contained in the cleaning liquid.

### (Polyamine Compound)

Examples of the polyamine compound other than the amino alcohol and the amine compound having a cyclic structure include alkylene diamines such as ethylenediamine (EDA), 1,3-propanediamine (PDA), 1,2-propanediamine, and 1,3-butanediamine, and polyalkylene polyamines such as diethylenetriamine (DETA), triethylenetetramine (TETA), and tetraethylenepentamine.

For the amine compound, the amine compounds described in paragraphs [0034] to [0056] of the description of WO 2013/162020 can be applied, and the contents thereof are incorporated in this specification.

In view of greater excellence in defect suppression performance, the primary to tertiary amines preferably further have one or more hydrophilic groups in addition to one of the primary to tertiary amino groups. For the hydrophilic group, examples thereof include primary to tertiary amino groups and hydroxyl groups, with preferred being primary to tertiary amino groups or hydroxyl groups.

Examples of the amine compound as above include a polyamine compound having two or more primary to tertiary amino groups, an amino alcohol having one or more primary to tertiary amino groups and one or more hydroxyl groups, and of amine compounds having a cyclic structure, a compound having two or more hydrophilic groups.

The upper limit of the total number of hydrophilic groups in the amine compound is not particularly limited and is preferably not more than five and more preferably not more than four.

### <Quaternary Ammonium Compound>

The cleaning liquid preferably contains a quaternary ammonium compound as the amine compound Z.

The quaternary ammonium compound is not particularly limited as long as it is a quaternary ammonium cation-containing compound in which a nitrogen atom is attached to four hydrocarbon groups (preferably, alkyl groups) through substitution. Examples of the quaternary ammonium compound include quaternary ammonium hydroxide, quaternary ammonium fluoride, quaternary ammonium bromide, quaternary ammonium iodide, quaternary ammonium acetate, and quaternary ammonium carbonate.

For the quaternary ammonium compound, preferred is quaternary ammonium hydroxide represented by Formula (4).

(R⁸)₄N⁺OH⁻ (4)

In the formula, R⁸ represents an alkyl group that may have a hydroxy group or a phenyl group as a substituent. The four R⁸'s may be the same as or different.

For the alkyl group represented by R⁸, an alkyl group having 1 to 4 carbon atoms is preferred, and a methyl group or an ethyl group is more preferred.

For the alkyl group that may have a hydroxy group or a phenyl group as represented by R⁸, preferred is a methyl group, an ethyl group, a propyl group, a butyl group, a 2-hydroxyethyl group, or a benzyl group, more preferred is a methyl group, an ethyl group, a propyl group, a butyl group, or a 2-hydroxyethyl group, and even more preferred is a methyl group, an ethyl group, or a 2-hydroxyethyl group.

Examples of the quaternary ammonium compound include tetramethylammonium hydroxide (TMAH), trimethylethylammonium hydroxide (TMEAH), dimethyldiethylammonium hydroxide (DMDEAH), methyltriethylammonium hydroxide (MTEAH), tetraethylammonium hydroxide (TEAH), tetrapropylammonium hydroxide (TPAH), tetrabutylammonium hydroxide (TBAH), 2-hydroxyethyl trimethylammonium hydroxide (choline), bis(2-hydroxyethyl)dimethylammonium hydroxide, tri(2-hydroxyethyl)methylammonium hydroxide, tetra(2-hydroxyethyl)ammonium hydroxide, benzyltrimethylammonium hydroxide (BTMAH), and cetyltrimethylammonium hydroxide.

As examples of the quaternary ammonium compound other than the foregoing specific examples, the compounds described in paragraph [0021] of JP 2018-107353 A can be applied, and the contents thereof are incorporated in this specification.

For the quaternary ammonium compound used for the cleaning liquid, TEAH, TBAH, MTEAH, DMDEAH, or TPAH is preferred, and TEAH, TBAH, MTEAH, or TPAH is more preferred.

The quaternary ammonium compound preferably also has an asymmetric structure because this leads to excellent damage resistance. The quaternary ammonium compound “having an asymmetric structure” means that four hydrocarbon groups attached to a nitrogen atom through substitution are different from one another.

Examples of the quaternary ammonium compound having an asymmetric structure include TMEAH, DEDMAH, TEMAH, choline, and bis(2-hydroxyethyl)dimethylammonium hydroxide.

The quaternary ammonium compounds may be used singly or in combination of two or more.

When the cleaning liquid contains the quaternary ammonium compound, the content of the quaternary ammonium compound is preferably 0.0001 to 15 mass %, more preferably 0.01 to 10 mass %, and still more preferably 0.1 to 5 mass % based on the total mass of the cleaning liquid.

When the cleaning liquid contains the quaternary ammonium compound, the content of the quaternary ammonium compound is preferably 0.1 to 35 mass %, more preferably 2 to 25 mass %, and still more preferably 6 to 18 mass % based on the total mass of the components, excluding solvent, contained in the cleaning liquid.

In view of excellence in temporal stability of the cleaning liquid, the amine compound Z preferably has a first acid dissociation constant (pKa1) of not less than 8.5, more preferably not less than 8.6, and still more preferably not less than 8.7. While the upper limit of the first acid dissociation constant is not particularly limited, the upper limit is preferably not more than 12.0.

When the cleaning liquid contains two or more amine compounds Z, at least one amine compound Z (preferably, the amine compound Z having the largest content) preferably satisfies the above range of the first acid dissociation constant (pKa1).

In the present specification, the first acid dissociation constant (pKa1) is a value obtained using SC-Database (http://acadsoft.co.uk/scdbase/SCDB_software/scdb_download.htm).

Among the above-described examples of the amine compound Z, preferable examples include the primary to tertiary amines corresponding to amino alcohol, and the quaternary ammonium compound. More preferable examples include MEA (pKa1: 9.5), AMP (pKa1: 9.7), DEA (pKa1: 8.7), AEE (pKa1: 10.6), AAE (pKa1: 10.8), TEAH (pKa1: >14.0), TBAH (pKa1: >14.0), MTEAH (pKa1: >14.0), DEDMAH (pKa1: >14.0), TPAH (pKa1: >14.0), and N-MAMP (pKa1: 9.72). Still more preferable examples include MEA, AMP, AEE, TEAH, TBAH, MTEAH, and N-MAMP. Particularly preferable examples include MEA, AMP, and AEE.

The cleaning liquid may contain one amine compound Z alone or two or more amine compounds Z. In view of excellence in cleaning performance, the cleaning liquid preferably contains two or more amine compounds Z.

When two or more amine compounds Z are contained, it is assumed that a first amine compound Z of the two or more amine compounds Z has the highest content, and a second amine compound Z of the two or more amine compounds Z has the second highest content. In this case, the mass ratio of the content of the second amine compound Z to the content of the first amine compound Z (the content of the second amine compound Z/the content of the first amine compound Z) is preferably 0.01 to 1, more preferably 0.05 to 1, and still more preferably 0.1 to 1. It should be noted that the content of the first amine compound Z may be substantially the same as the content of the second amine compound Z.

When the cleaning liquid contains the amine compound Z, the content of the amine compound Z is preferably 0.5 to 20 mass %, more preferably 1 to 15 mass %, and still more preferably 2 to 10 mass % based on the total mass of the cleaning liquid.

When the cleaning liquid contains the amine compound Z, the content of the amine compound Z is preferably 10 to 98 mass %, more preferably 30 to 90 mass %, and still more preferably 45 to 85 mass % based on the total mass of the components, excluding solvent, contained in the cleaning liquid.

When the content is equal to or greater than the lower limit of each of the above ranges, the residue removability of the cleaning liquid is easily improved, resulting in greater excellence in cleaning performance. When the content is not more than the upper limit of each of the above ranges, metal (for instance, Co, W, and Cu) is less likely to corrode.

The mass ratio of the content of the amine compound Z to the content of the amine compound Y0 (the amine compound Z/the amine compound Y0) is preferably 0.01 to 1000, more preferably 0.01 to 100, still more preferably 1 to 100, particularly preferably 2 to 100, and most preferably 32 to 100.

### [Chelating Agent]

The cleaning liquid also preferably contains a chelating agent.

The chelating agent used in the cleaning liquid is a compound that has a function of chelating with metal contained in a residue in a cleaning step of a semiconductor substrate. In particular, such a compound is preferable that has in its molecule two or more functional groups (coordination groups) that form coordinate bonds with metal ions. It should be noted that the chelating agent does not include any of the above-described amine compound Y0 and amine compound Z.

The chelating agent is preferably different also from an anticorrosive, described later.

Examples of the coordination groups included in the chelating agent include an acid group and a cationic group. Examples of the acid group include a carboxy group, a phosphonic acid group, a sulfo group, and a phenolic hydroxy group. Examples of the cationic group include an amino group.

The chelating agent used in the cleaning liquid preferably has an acid group as a coordination group, and more preferably has at least one coordination group selected from a carboxy group and a phosphonic acid group.

Examples of the chelating agent include an organic chelating agent and an inorganic chelating agent.

The organic chelating agent is a chelating agent constituted of an organic compound, and examples thereof include a carboxylic acid-based chelating agent having a carboxy group as the coordination group, and a phosphonic acid-based chelating agent having a phosphonic acid group as the coordination group.

Examples of the inorganic chelating agent include condensed phosphoric acid and salts thereof.

For the chelating agent, the organic chelating agent is preferred, and an organic chelating agent having at least one coordination group selected from a carboxy group and a phosphonic acid group is more preferred.

The chelating agent is preferably of low molecular weight. Specifically, the molecular weight of the chelating agent is preferably not more than 600, and more preferably not more than 450. The lower limit of the molecular weight is, for instance, 60.

When the chelating agent is the organic chelating agent, the number of carbon atoms is preferably not more than 15. The lower limit of the number of carbon atoms is, for instance, 2.

### <Carboxylic Acid-Based Chelating Agent>

The carboxylic acid-based chelating agent is a chelating agent having in its molecule a carboxy group as the coordination group, and examples thereof include an aminopolycarboxylic acid-based chelating agent, an amino acid-based chelating agent, and an aliphatic carboxylic acid-based chelating agent.

Examples of the aminopolycarboxylic acid-based chelating agent include butylene diamine tetraacetic acid, diethylenetriamine pentaacetic acid (DTPA), ethylenediamine tetrapropionic acid, triethylenetetramine hexacetic acid, 1,3-diamino-2-hydroxypropane-N,N,N′,N′-tetraacetic acid, propylenediamine tetraacetic acid, ethylenediamine tetraacetic acid (EDTA), trans-1,2-diaminocyclohexane tetraacetic acid, ethylenediamine diacetic acid, ethylenediamine dipropionic acid, 1,6-hexamethylene-diamine-N,N,N′,N′-tetraacetic acid, N,N-bis(2-hydroxybenzyl)ethylenediamine-N,N-diacetic acid, diaminopropane tetraacetic acid, 1,4,7,10-tetraazacyclododecane-tetraacetic acid, diaminopropanol tetraacetic acid, (hydroxyethyl)ethylenediamine triacetic acid, and iminodiacetic acid (IDA).

In particular, diethylene triamine pentaacetic acid (DTPA) is preferable.

Examples of the amino acid-based chelating agent include glycine, serine, α-alanine (2-aminopropionic acid), β-alanine (3-aminopropionic acid), lysine, leucine, isoleucine, cystine, ethionine, threonine, tryptophan, tyrosine, valine, histidine, histidine derivatives, asparagine, aspartic acid, glutamine, glutamic acid, arginine, proline, methionine, phenylalanine, the compounds described in paragraphs [0021] to [0023] of JP 2016-086094 A (the contents thereof are incorporated in this specification), and salts thereof. For the histidine derivatives, the compounds described in, for instance, JP 2015-165561 A and JP 2015-165562 A can be applied, and the contents thereof are incorporated in this specification. Examples of the salts include: alkali metal salts such as sodium salts and potassium salts; ammonium salts; carbonates; and acetates.

It should be noted, however, that an amino acid having a thiol group and a salt thereof are not included in the chelating agent.

Examples of the aliphatic carboxylic acid-based chelating agent include oxalic acid, malonic acid, succinic acid, glutaric acid, adipic acid, pimelic acid, sebacic acid, and maleic acid. In particular, adipic acid is preferable.

Adipic acid is remarkably effective and greatly improves the performance of the cleaning liquid, as compared with other chelating agents. The effectiveness of adipic acid applies not only in residue removability but also in corrosion resistance. It remains to be seen as to a detailed mechanism of how adipic acid can be thus peculiarly effective. A possible explanation, however, is that the effectiveness of adipic acid derives from such facts as: adipic acid is a dicarboxylic acid; the number of carbons is neither too hydrophilic nor too hydrophobic; and adipic acid forms a stable ring structure when forming a complex with a metal.

For the carboxylic acid-based chelating agent, preferred is the aminopolycarboxylic acid-based chelating agent, the amino acid-based chelating agent, or the aliphatic carboxylic acid-based chelating agent, more preferred is DTPA, EDTA, trans-1,2-diaminocyclohexane tetraacetic acid, IDA, arginine, glycine, β-alanine, or adipic acid, and even more preferred is DTPA or adipic acid.

### <Phosphonic Acid-Based Chelating Agent>

The phosphonic acid-based chelating agent is a chelating agent having in its molecule at least one phosphonic acid group. Examples of the phosphonic acid-based chelating agent include compounds represented by Formulae (1), (2) and (3) below.

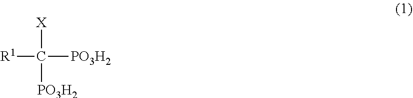

In the formula, X represents a hydrogen atom or a hydroxy group, and R¹ represents a hydrogen atom or an alkyl group having 1 to 10 carbon atoms.

The alkyl group having 1 to 10 carbon atoms represented by R¹ in Formula (1) may be any of linear, branched, and cyclic groups.

For R¹ in Formula (1), an alkyl group having 1 to 6 carbon atoms is preferred, and a methyl group, an ethyl group, an n-propyl group, or an isopropyl group is more preferred.

It should be noted that n- represents a normal-type in specific examples of an alkyl group described in the present specification.

For X in Formula (1), a hydroxy group is preferred.

For the phosphonic acid-based chelating agent represented by Formula (1), preferred is ethylidenediphosphonic acid, 1-hydroxyethylidene-1,1′-diphosphonic acid (HEDP), 1-hydroxypropylidene-1,1′-diphosphonic acid, or 1-hydroxybutylidene-1,1′-diphosphonic acid.

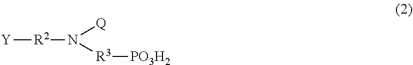

In the formula, Q represents a hydrogen atom or R³—PO₃H₂, R² and R³ each independently represent an alkylene group, and Y represents a hydrogen atom, —R³—PO₃H₂, or a group represented by the following Formula (4).

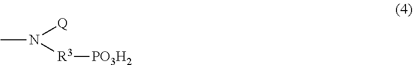

In the formula, Q and R³ are respectively the same as Q and R³ in Formula (2).

Examples of the alkylene group represented by R² in Formula (2) include a linear or branched alkylene group having 1 to 12 carbon atoms.

For the alkylene group represented by R², a linear or branched alkylene group having 1 to 6 carbon atoms is preferred, a linear or branched alkylene group having 1 to 4 carbon atoms is more preferred, and an ethylene group is even more preferred.

For the alkylene group represented by R³ in Formulae (2) and (4), examples thereof include a linear or branched alkylene group having 1 to 10 carbon atoms, with a linear or branched alkylene group having 1 to 4 carbon atoms being preferred, a methylene group or an ethylene group being more preferred, and a methylene group being even more preferred.

For Q in Formulae (2) and (4), —R³—PO₃H₂ is more preferred.

For Y in Formula (2), —R³—PO₃H₂ or a group represented by Formula (4) is preferred, and a group represented by Formula (4) is more preferred.

For the phosphonic acid-based chelating agent represented by Formula (2), preferred is ethylaminobis(methylenephosphonic acid), dodecylaminobis(methylenephosphonic acid), nitrilotris(methylenephosphonic acid) (NTPO), ethylenediamine bis(methylenephosphonic acid) (EDDPO), 1,3-propylenediamine bis(methylenephosphonic acid), ethylenediamine tetra(methylenephosphonic acid) (EDTPO), ethylenediamine tetra(ethylenephosphonic acid), 1,3-propylenediamine tetra(methylenephosphonic acid) (PDTMP), 1,2-diaminopropane tetra(methylenephosphonic acid), or 1,6-hexamethylenediamine tetra(methylenephosphonic acid).

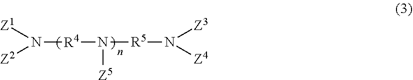

In the formula, R⁴ and R⁵ each independently represent an alkylene group having 1 to 4 carbon atoms, n represents an integer of 1 to 4, and at least four of Z¹ to Z⁴ and n moieties of Z⁵s represent a phosphonic acid group-containing alkyl group while the remainder represents an alkyl group.

The alkylene group having 1 to 4 carbon atoms represented by R⁴ and R⁵ in Formula (3) may be a linear or branched group. The alkylene group having 1 to 4 carbon atoms represented by R⁴ and R⁵ in Formula (3) may be a linear or branched group. Examples of the alkylene group having 1 to 4 carbon atoms represented by R⁴ and R⁵ include a methylene group, an ethylene group, a propylene group, a trimethylene group, an ethylmethylene group, a tetramethylene group, a 2-methylpropylene group, a 2-methyltrimethylene group, and an ethylethylene group, with an ethylene group being preferred.

For n in Formula (3), 1 or 2 is preferred.

Examples of an alkyl group in the alkyl group and the phosphonic acid group-containing alkyl group represented by Z¹ to Z⁵ in Formula (3) include a linear or branched alkyl group having 1 to 4 carbon atoms, with a methyl group being preferred.

The number of phosphonic acid groups in the phosphonic acid group-containing alkyl group represented by Z¹ to Z⁵ is preferably one or two and more preferably one.

Examples of the phosphonic acid group-containing alkyl group represented by Z¹ to Z⁵ include a linear or branched alkyl group with 1 to 4 carbon atoms having one or two phosphonic acid groups, with a (mono)phosphonomethyl group or a (mono)phosphonoethyl group being preferred, and a (mono)phosphonomethyl group being more preferred.

For Z¹ to Z⁵ in the formula (3), it is preferable that each of Z¹ to Z⁴ and n moieties of Z⁵s be the foregoing phosphonic acid group-containing alkyl group.

For the phosphonic acid-based chelating agent represented by Formula (3), preferred is diethylenetriamine penta(methylenephosphonic acid) (DEPPO), diethylenetriamine penta(ethylenephosphonic acid), triethylenetetramine hexa(methylenephosphonic acid), or triethylenetetramine hexa(ethylenephosphonic acid).

For the phosphonic acid-based chelating agent used in the cleaning liquid, not only the phosphonic acid-based chelating agents represented by Formulae (1), (2) and (3) above but also the compounds described in paragraphs [0026] to [0036] of the description of WO 2018/020878 and the compounds ((co)polymers) described in paragraphs [0031] to [0046] of the description of WO 2018/030006 can be applied, and the contents thereof are incorporated in this specification.

For the phosphonic acid-based chelating agent used in the cleaning liquid, those compounds listed as preferable specific examples of the phosphonic acid-based chelating agents represented by Formulae (1), (2) and (3) above are preferred, HEDP, NTPO, EDTPO, or DEPPO is more preferred, and HEDP or EDTPO is even more preferred.

The phosphonic acid-based chelating agents may be used singly or in combination of two or more.

A commercial phosphonic acid-based chelating agent may contain water such as distilled water, deionized water and ultrapure water in addition to a phosphonic acid-based chelating agent, and it is no problem to use such a phosphonic acid-based chelating agent containing water.

Examples of the condensed phosphoric acid and salts thereof which are the inorganic chelating agents include pyrophosphoric acid and salts thereof, metaphosphoric acid and salts thereof, tripolyphosphoric acid and salts thereof, and hexametaphosphoric acid and salts thereof.

For the chelating agent, preferred is DTPA, EDTA, trans-1,2-diaminocyclohexane tetraacetic acid, IDA, arginine, glycine, β-alanine, oxalic acid, HEDP, NTPO, EDTPO, or DEPPO, more preferred is DTPA, EDTA, IDA, glycine, cysteine, HEDP, or EDTPO, and still more preferred is DTPA.

The chelating agents may be used singly or in combination of two or more.

The content of the chelating agent (the total content when two or more chelating agents are contained) in the cleaning liquid is not particularly limited. Preferably, the content of the chelating agent is not more than 20 mass % based on the total mass of the cleaning liquid because this leads to excellent defect suppression performance. More preferably, the content of the chelating agent is not more than 15 mass %, and even more preferably not more than 10 mass % based on the total mass of the cleaning liquid because this leads to greater excellence in defect suppression performance for a metal film. The lower limit thereof is not particularly limited and is preferably not less than 0.01 mass %, and more preferably not less than 0.1 mass % based on the total mass of the cleaning liquid because this leads to greater excellence in performance in suppressing a change in the pH caused by dilution.

The content of the chelating agent (total content when two or more chelating agents are contained) in the cleaning liquid is not particularly limited. Preferably, the content of the chelating agent is not more than 40 mass % based on the total mass of the components, excluding solvent, contained in the cleaning liquid in view of excellence in defect suppression performance. More preferably, the content of the chelating agent is not more than 20 mass %, and still more preferably not more than 10 mass % based on the total mass of the components, excluding solvent, contained in the cleaning liquid in view of greater excellence in defect suppression performance for a metal film. The lower limit is not particularly limited, but is preferably not less than 0.1 mass %, and more preferably not less than 0.8 mass % based on the total mass of the components, excluding solvent, contained in the cleaning liquid because this leads to greater excellence in performance in suppressing a change in the pH caused by dilution.

The mass ratio of the content of the amine compound Y0 to the content of the chelating agent (the amine compound Y0/the chelating agent) is preferably not less than 0.05 and more preferably not less than 0.1 because this prevents conflict between the effect of the amine compound Y0 and the effect of the chelating agent, resulting in greater excellence in cleaning performance. The upper limit of the mass ratio is preferably not more than 10, more preferably not more than 5, and still more preferably not more than 3, in view of obtaining a sufficient effect of improving cleaning performance from the chelating agent and thus obtaining greater excellence in cleaning performance.

### [Anticorrosive]

The cleaning liquid may contain an anticorrosive.

Examples of the anticorrosive include: a heterocyclic compound, which has a heterocyclic structure; a hydroxyl carboxylic acid; a hydroxylamine compound; an ascorbic acid compound; a catechol compound; a reducing sulfur compound; a hydrazide compound; and a biguanide compound.

The anticorrosive is preferably different from the above-described components.

Also, in the cleaning liquid, the anticorrosive preferably includes a reducing agent (an anticorrosive serving as a reducing agent).

The reducing agent is a compound having an oxidative effect and having the function of oxidizing OH— ions or dissolved oxygen contained in the cleaning liquid, and is also called an oxygen scavenger. When the cleaning liquid contains a reducing agent as an anticorrosive, the cleaning liquid is greater in excellence in corrosion prevention performance.

Examples of the anticorrosive serving as a reducing agent include a hydroxylamine compound, an ascorbic acid compound, a catechol compound, a reducing sulfur compound, and a hydrazide compound.

It should be noted that the anticorrosive is preferably a component different from the above-described components.

### <Heterocyclic Compound>

The cleaning liquid may contain a heterocyclic compound as an anticorrosive.

The heterocyclic compound is a compound having in its molecule a heterocyclic structure. The heterocyclic structure of the heterocyclic compound is not particularly limited. For instance, the heterocyclic structure is a heterocyclic ring (nitrogen-containing heterocyclic ring) in which at least one of the atoms constituting the ring is a nitrogen atom. Examples of the heterocyclic compound exclude the amine compound Y0 and the amine compound Z.

Examples of the heterocyclic compound having a nitrogen-containing heterocyclic ring include a nitrogen-containing heteroaromatic compound such as an azole compound.

The azole compound is a compound having a five-membered heterocyclic ring containing at least one nitrogen atom and having aromatic properties.

The number of nitrogen atoms included in the five-membered heterocyclic ring of the azole compound is not particularly limited, and is preferably 1 to 4 and more preferably 1 to 3.

The azole compound may also have a substituent on the five-membered heterocyclic ring. Examples of the substituent include a hydroxy group, a carboxy group, a mercapto group, an amino group, an alkyl group having 1 to 4 carbon atoms that may have an amino group, and a 2-imidazolyl group.

Examples of the azole compound include: an imidazole compound, in which one of the atoms constituting an azole ring is a nitrogen atom; a pyrazole compound, in which two of the atoms constituting an azole ring are nitrogen atoms; a thiazole compound, in which one of the atoms constituting an azole ring is a nitrogen atom and another one of the atoms is a sulfur atom; a triazole compound, in which three of the atoms constituting an azole ring are nitrogen atoms; and a tetrazole compound, in which four of the atoms constituting an azole ring are nitrogen atoms.

Examples of the imidazole compound include imidazole, 1-methylimidazole, 2-methylimidazole, 5-methylimidazole, 1,2-dimethylimidazole, 2-mercaptoimidazole, 4,5-dimethyl-2-mercaptoimidazole, 4-hydroxyimidazole, 2,2′-biimidazole, 4-imidazolecarboxylic acid, histamine, benzimidazole, and purine bases (such as adenine).

Examples of the pyrazole compound include pyrazole, 4-pyrazolecarboxylic acid, 1-methylpyrazole, 3-methylpyrazole, 3-amino-5-methylpyrazole, 3-amino-5-hydroxypyrazole, 3-aminopyrazole, and 4-aminopyrazole.

Examples of the thiazole compound include 2,4-dimethylthiazole, benzothiazole, and 2-mercaptobenzothiazole.

Examples of the triazole compound include 1,2,4-triazole, 3-methyl-1,2,4-triazole, 3-amino-1,2,4-triazole, 1,2,3-triazole, 1-methyl-1,2,3-triazole, benzotriazole, 1-hydroxybenzotriazole, 1-dihydroxypropyl benzotriazole, 2,3-dicarboxypropyl benzotriazole, 4-hydroxybenzotriazole, 4-carboxybenzotriazole, and 5-methylbenzotriazole.

Examples of the tetrazole compound include 1H-tetrazole (1,2,3,4-tetrazole), 5-methyl-1,2,3,4-tetrazole, 5-amino-1,2,3,4-tetrazole, 1,5-pentamethylene tetrazole, 1-phenyl-5-mercaptotetrazole, and 1-(2-dimethylaminoethyl)-5-mercaptotetrazole.

The azole compound is preferably an imidazole compound or a pyrazole compound, and more preferably adenine, pyrazole, or 3-amino-5-methylpyrazole.

The heterocyclic compounds (preferably azole compounds) may be used singly or in combination of two or more.

When the cleaning liquid contains the heterocyclic compound (preferably an azole compound), the content of the heterocyclic compound is preferably 0.01 to 10 mass %, more preferably 0.05 to 5 mass %, and still more preferably 0.1 to 3 mass % based on the total mass of the cleaning liquid.

When the cleaning liquid contains the heterocyclic compound, the content of the heterocyclic compound is preferably 0.1 to 30 mass %, more preferably 0.5 to 20 mass %, and still more preferably 1 to 10 mass % based on the total mass of the components, excluding solvent, contained in the cleaning liquid.

### <Biguanide Compound>

The cleaning liquid may contain a biguanide compound.

The biguanide compound is a compound having a biguanide group or a salt thereof. The number of biguanide groups in the biguanide compound is not particularly limited; the biguanide compound may have a plurality of biguanide groups.

For the biguanide compound, the compounds described in paragraphs [0034] to [0055] of JP 2017-504190 A can be applied, and the contents thereof are incorporated in this specification.

Preferable examples of the compound having a biguanide group include ethylene dibiguanide, propylene dibiguanide, tetramethylene dibiguanide, pentamethylene dibiguanide, hexamethylene dibiguanide, heptamethylene dibiguanide, octamethylene dibiguanide, 1,1′-hexamethylenebis(5-(p-chlorophenyl) biguanide)) (chlorhexidine), 2-(benzyloxymethyl)pentane-1,5-bis(5-hexylbiguanide), 2-(phenylthiomethyl)pentane-1,5-bis(5-phenethylbiguanide), 3-(phenylthio)hexane-1,6-bis(5-hexylbiguanide), 3-(phenylthio)hexane-1,6-bis(5-cyclohexylbiguanide), 3-(benzylthio)hexane-1,6-bis(5-hexylbiguanide), and 3-(benzylthio)hexane-1,6-bis(5-cyclohexylbiguanide), with chlorhexidine being more preferable.

The salt of the compound having a biguanide group is preferably hydrochloride, acetate, or gluconate, and more preferably gluconate.

The biguanide compound is preferably chlorhexidine gluconate (CHG).

The biguanide compounds may be used singly or in combination of two or more.

When the cleaning liquid contains the biguanide compound, the content of the biguanide compound is preferably 0.01 to 10 mass %, more preferably 0.05 to 5 mass %, and still more preferably 0.1 to 3 mass % based on the total mass of the cleaning liquid.

When the cleaning liquid contains the biguanide compound, the content of the biguanide compound is preferably 0.1 to 30 mass %, more preferably 0.5 to 20 mass %, and still more preferably 1 to 10 mass % based on the total mass of the components, excluding solvent, contained in the cleaning liquid.

The cleaning liquid also preferably contains one or both (preferably both) of the heterocyclic compound (preferably an azole compound) and the biguanide compound. The total content of these compounds is preferably 0.01 to 10 mass %, more preferably 0.05 to 5 mass %, and still more preferably 0.1 to 3 mass % based on the total mass of the cleaning liquid.

The total content of these compounds is preferably 0.1 to 30 mass %, more preferably 0.5 to 20 mass %, and still more preferably 1 to 10 mass % based on the total mass of the components, excluding solvent, contained in the cleaning liquid.

### <Ascorbic Acid Compound>

The ascorbic acid compound refers to at least one selected from the group consisting of ascorbic acid, an ascorbic acid derivative, and salts thereof.

Examples of the ascorbic acid derivative include an ascorbic acid phosphoric acid ester and an ascorbic acid sulfuric acid ester.

The ascorbic acid compound is preferably ascorbic acid, ascorbic acid phosphoric acid ester, or ascorbic acid sulfuric acid ester, and more preferably ascorbic acid.

The ascorbic acid compounds may be used singly or in combination of two or more.

When the cleaning liquid contains the ascorbic acid compound, the content of the ascorbic acid compound is preferably 0.01 to 10 mass %, more preferably 0.05 to 7 mass %, and still more preferably 0.5 to 5 mass % based on the total mass of the cleaning liquid.

When the cleaning liquid contains the ascorbic acid compound, the content of the ascorbic acid compound is preferably 0.5 to 50 mass %, more preferably 1 to 30 mass %, and still more preferably 10 to 25 mass % based on the total mass of the components, excluding solvent, contained in the cleaning liquid.

### <Hydroxylamine Compound>

The hydroxylamine compound refers to at least one selected from the group consisting of hydroxylamine (NH2OH), a hydroxylamine derivative, and salts thereof. The hydroxylamine derivative refers to a compound of hydroxylamine (NH2OH) obtained through substitution with at least one organic group.

A salt of hydroxylamine or a hydroxylamine derivative may be an inorganic or organic acid salt of hydroxylamine or a hydroxylamine derivative. For the salt of hydroxylamine or a hydroxylamine derivative, preferred is a salt thereof with an inorganic acid in which at least one non-metal selected from the group consisting of Cl, S, N and P is bonded to hydrogen, and more preferred is hydrochloride, sulfate, or nitrate.

Examples of the hydroxylamine compound include a compound represented by Formula (3) and a salt thereof.

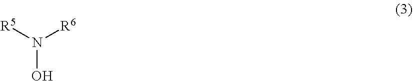

In Formula (3), R⁵ and R⁶ each independently represent a hydrogen atom or an organic group.

The organic group represented by R⁵ and R⁶ is preferably an alkyl group having 1 to 6 carbon atoms. The alkyl group having 1 to 6 carbon atoms may be any of linear, branched, and cyclic groups.

At least one of R⁵ and R⁶ is preferably an organic group (more preferably an alkyl group having 1 to 6 carbon atoms).

The alkyl group having 1 to 6 carbon atoms is preferably an ethyl group or an n-propyl group, and more preferably an ethyl group.

Examples of the hydroxylamine compound include hydroxylamine, O-methylhydroxylamine, O-ethylhydroxylamine, N-methylhydroxylamine, N,N-dimethylhydroxylamine, N,O-dimethylhydroxylamine, N-ethylhydroxylamine, N,N-diethylhydroxylamine, N,O-diethylhydroxylamine, O,N,N-trimethylhydroxylamine, N,N-dicarboxyethylhydroxylamine, and N,N-disulfoethylhydroxylamine.

In particular, N-ethylhydroxylamine, N,N-diethylhydroxylamine (DEHA), or N-n-propylhydroxylamine is preferable, and DEHA is more preferable.

The hydroxylamine compounds may be used singly or in combination of two or more.

When the cleaning liquid contains the hydroxylamine compound, the content of the hydroxylamine compound is preferably 0.01 to 10 mass %, more preferably 0.05 to 7 mass %, and still more preferably 0.5 to 5 mass % based on the total mass of the cleaning liquid.

When the cleaning liquid contains the hydroxylamine compound, the content of the hydroxylamine compound is preferably 0.5 to 50 mass %, more preferably 1 to 30 mass %, and still more preferably 10 to 25 mass % based on the total mass of the components, excluding solvent, contained in the cleaning liquid.

The cleaning liquid also preferably contains one or both of the ascorbic acid compound and the hydroxylamine compound. The total content of these compounds is preferably 0.01 to 10 mass %, more preferably 0.05 to 7 mass %, and still more preferably 0.5 to 5 mass % based on the total mass of the cleaning liquid.

The total content of these compounds is preferably 0.5 to 50 mass %, more preferably 1 to 30 mass %, and still more preferably 10 to 25 mass % based on the total mass of the components, excluding solvent, contained in the cleaning liquid.

### <Catechol Compound>

The catechol compound refers to at least one selected from the group consisting of pyrocatechol(benzene-1,2-diol) and a catechol derivative.

The catechol derivative refers to a compound of pyrocatechol obtained through substitution with at least one substituent. Examples of the substituent that the catechol derivative has include a hydroxy group, a carboxy group, a carboxylic acid ester group, a sulfo group, a sulfonic acid ester group, an alkyl group (preferably with 1 to 6 carbon atoms and more preferably with 1 to 4 carbon atoms), and an aryl group (preferably a phenyl group). The carboxy group and the sulfo group that the catechol derivative has as substituents may be salts with a cation. The alkyl group and the aryl group that the catechol derivative has as substituents may further have a substituent.

Examples of the catechol compound include pyrocatechol, 4-tert-butylcatechol, pyrogallol, gallic acid, methyl gallate, 1,2,4-benzenetriol, and tiron.

### <Hydrazide Compound>

The hydrazide compound refers to a compound obtained by substituting a hydroxy group of an acid with a hydrazino group (—NN—NH₂), and a derivative of such compound (a compound having a hydrazino group obtained through substitution with at least one substituent).

The hydrazide compound may have two or more hydrazino groups.

Examples of the hydrazide compound include carboxylic acid hydrazide and sulfonic acid hydrazide, and carbohydrazide (CHZ) is preferable.

### <Reducing Sulfur Compound>

The reducing sulfur compound is not particularly limited as long as the reducing sulfur compound contains a sulfur atom and has a function as a reducing agent. Examples of such reducing sulfur compound include cysteine, mercaptosuccinic acid, dithiodiglycerol, bis(2,3-dihydroxypropylthio)ethylene, sodium 3-(2,3-dihydroxypropylthio)-2-methyl-propylsulfonate, 1-thioglycerol, sodium 3-mercapto-1-propanesulfonate, 2-mercaptoethanol, thioglycolic acid, and 3-mercapto-1-propanol.

In particular, a compound having an SH group (mercapto compound) is preferable, cysteine, 1-thioglycerol, sodium 3-mercapto-1-propanesulfonate, 2-mercaptoethanol, 3-mercapto-1-propanol, or thioglycolic acid is more preferable, and cysteine is still more preferable.

The reducing sulfur compounds may be used singly or in combination of two or more.

When the cleaning liquid contains the reducing sulfur compound, the content of the reducing sulfur compound is preferably 0.001 to 10 mass %, more preferably 0.05 to 5 mass %, and still more preferably 0.2 to 0.8 mass % based on the total mass of the cleaning liquid.

When the cleaning liquid contains the reducing sulfur compound, the content of the reducing sulfur compound is preferably 0.05 to 45 mass %, more preferably 0.1 to 35 mass %, and still more preferably 0.7 to 25 mass % based on the total mass of the components, excluding solvent, contained in the cleaning liquid.

### <Hydroxycarboxylic Acid>

The hydroxycarboxylic acid is a compound having in its molecule one or more hydroxyl groups and one or more carboxy groups.

It should be noted, however, that a compound corresponding to an amino acid is not included in the hydroxycarboxylic acid described herein.

For the hydroxyl group in the hydroxycarboxylic acid, usually one other than an aromatic hydroxyl group is preferable.

The cleaning liquid preferably contains a hydroxycarboxylic acid in view of further improvement in cleaning performance (in particular, cleaning performance for a metal film containing Co or Cu) while maintaining the corrosion prevention performance of the cleaning liquid (in particular, corrosion prevention property for a metal film containing Co or Cu).

Examples of the hydroxycarboxylic acid include citric acid, malic acid, citric acid, glycolic acid, gluconic acid, heptonic acid, tartaric acid, and lactic acid. Gluconic acid, glycolic acid, malic acid, tartaric acid, or citric acid is preferred, and gluconic acid or citric acid is more preferred.

The hydroxycarboxylic acids may be used singly or in combination of two or more.

When the cleaning liquid contains the hydroxycarboxylic acid, the content of the hydroxycarboxylic acid is preferably 0.001 to 10 mass %, more preferably 0.05 to 5 mass %, and still more preferably 0.2 to 0.8 mass % based on the total mass of the cleaning liquid.

When the cleaning liquid contains a hydroxycarboxylic acid, the content of the hydroxycarboxylic acid is preferably 0.05 to 45 mass %, more preferably 0.1 to 35 mass %, and still more preferably 0.7 to 25 mass % based on the total mass of the components, excluding solvent, contained in the cleaning liquid.

The cleaning liquid also preferably contains one or both of the reducing sulfur compound and the hydroxycarboxylic acid. The total content of the compound and the acid is preferably 0.001 to 10 mass %, more preferably 0.05 to 5 mass %, and still more preferably 0.2 to 0.8 mass % based on the total mass of the cleaning liquid.

The total content of the compound and the acid is preferably 0.05 to 45 mass %, more preferably 0.1 to 35 mass %, and still more preferably 0.7 to 25 mass % based on the total mass of the components, excluding solvent, contained in the cleaning liquid.

Also, the mass ratio of the content of the compound Y0 to the total content (the content of the compound Y0/the total content of the reducing sulfur compound and the hydroxycarboxylic acid) is preferably 0.01 to 100, more preferably 0.05 to 5, and still more preferably 0.3 to 1.5.

The cleaning liquid may contain other anticorrosives than the foregoing components.

Exemplary other anticorrosives include sugars such as fructose, glucose, and ribose, polyols such as ethylene glycol, propylene glycol, and glycerin, polycarboxylic acids such as polyacrylic acid, polymaleic acid, and copolymers thereof, polyvinylpyrrolidone, cyanuric acid, barbituric acid and its derivatives, glucuronic acid, squaric acid, α-keto acid, adenosine and its derivatives, phenanthroline, resorcinol, hydroquinone, nicotinamide and its derivatives, flavonol and its derivatives, anthocyanin and its derivatives, and combinations thereof.

The anticorrosives may be used singly or in combination of two or more.

In view of greater excellence in corrosion prevention performance, the cleaning liquid preferably contains two or more anticorrosives, and more preferably contains three or more anticorrosives.

The content of the anticorrosive is preferably 0.01 to 20 mass %, more preferably 0.1 to 10 mass %, and still more preferably 1 to 5 mass % based on the total mass of the cleaning liquid.

The content of the anticorrosive is preferably 1 to 65 mass %, more preferably 10 to 55 mass %, and still more preferably 20 to 45 mass % based on the total mass of the components, excluding solvent, contained in the cleaning liquid.

The mass ratio of the content of the compound Y0 to the content of the anticorrosive (the content of the compound Y0/the content of the anticorrosive) is preferably 0.001 to 50, more preferably 0.02 to 5, and still more preferably 0.04 to 3.

### [pH Adjuster]

The cleaning liquid may contain a pH adjuster to adjust and maintain the pH of the cleaning liquid. Examples of the pH adjuster include a basic compound and an acidic compound other than the above-described components.

The pH adjuster refers to a component different from each of the above-described components. It should be noted, however, that it is allowable to adjust the pH of the cleaning liquid by adjusting the content of each of the above-described components to be added.

Examples of the basic compound include a basic organic compound and a basic inorganic compound.

The basic organic compound is a basic organic compound different from the foregoing amine compound Y0. Examples of the basic organic compound include an amine oxide, nitro, nitroso, oxime, ketoxime, aldoxime, lactam, isocyanides, and urea.

Examples of the basic inorganic compound include an alkali metal hydroxide, an alkaline earth metal hydroxide, and ammonia.

Examples of the alkali metal hydroxide include lithium hydroxide, sodium hydroxide, potassium hydroxide, and cesium hydroxide. Examples of the alkaline earth metal hydroxide include calcium hydroxide, strontium hydroxide, and barium hydroxide.

Examples of the acidic compound include an inorganic acid and an organic acid.

Examples of the inorganic acid include hydrochloric acid, sulfuric acid, sulfurous acid, nitric acid, nitrous acid, phosphoric acid, boric acid, and hexafluorophosphoric acid. Salts of the inorganic acids may also be used, and examples thereof include ammonium salts of the inorganic acids, more specifically, ammonium chloride, ammonium sulfate, ammonium sulfite, ammonium nitrate, ammonium nitrite, ammonium phosphate, ammonium borate, and ammonium hexafluorophosphate.

The organic acid is an organic compound having an acidic functional group and showing acidic properties (pH: less than 7.0) in an aqueous solution. Examples of the organic acid include lower aliphatic monocarboxylic acids (with 1 to 4 carbon atoms) such as formic acid, acetic acid, propionic acid, and butyric acid.

As the acidic compound, a salt of the acidic compound may be used as long as it forms an acid or an acid ion (anion) in an aqueous solution.

The pH adjusters may be used singly or in combination of two or more.

When the cleaning liquid contains the pH adjuster, the content of the pH adjuster is selected depending on the types and the amounts of other components and the pH of a target cleaning liquid, and is preferably 0.01 to 3 mass % and more preferably 0.05 to 2 mass % based on the total mass of the cleaning liquid.

When the cleaning liquid contains the pH adjuster, the content of the pH adjuster is preferably 0.05 to 30 mass %, and more preferably 0.1 to 22 mass % based on the total mass of the components, excluding solvent, contained in the cleaning liquid.

The cleaning liquid may contain other components such as a surfactant, a polymer, a fluorine compound, and/or an organic solvent.

For the surfactant, the surfactants described in paragraphs [0023] to [0044] of the description of WO 2018/151164 can be applied, and the contents thereof are incorporated in this specification.

For the polymer, the water-soluble polymers described in paragraphs [0043] to [0047] of JP 2016-171294 A can be applied, and the contents thereof are incorporated in this specification.

For the fluorine compound, the compounds described in paragraphs [0013] to [0015] of JP 2005-150236 A can be applied, and the contents thereof are incorporated in this specification.

For the organic solvent, any of known organic solvents may be used, and hydrophilic organic solvents such as alcohols and ketones are preferred. The organic solvents may be used singly or in combination of two or more.

The amounts of the surfactant, the polymer, fluorine compound and organic solvent for use are not particularly limited and may be suitably specified in the ranges that do not impair the effectiveness of the present invention.

The contents of the respective components above in the cleaning liquid can be measured by known methods such as gas chromatography-mass spectrometry (GC-MS), liquid chromatography-mass spectrometry (LC-MS), and ion-exchange chromatography (IC).

### [Physical Properties of Cleaning Liquid]

<pH>

The cleaning liquid shows alkaline properties. The pH of the cleaning liquid is 8.0 to 11.0, preferably 9.0 to 11.0, and more preferably 10.0 to 11.0.

The pH of the cleaning liquid can be measured with a known pH meter by the method according to JIS Z 8802-1984.

The temperature at which the pH is measured is 25° C.

### <Metal Content>

In the cleaning liquid, the content of each of metals (elemental metals Fe, Co, Na, K, Cu, Mg, Mn, Li, Al, Cr, Ni, Zn, Sn and Ag) contained as impurities in the liquid (calculated as the ion concentration) is preferably not more than 5 ppm by mass and more preferably not more than 1 ppm by mass. Since it is expected in manufacture of leading-edge semiconductor devices that a cleaning liquid with even higher purity should be required, the metal content is still more preferably less than 1 ppm by mass, that is, a value not more than the ppb-by-mass order, particularly preferably not more than 100 ppb by mass, and most preferably less than 10 ppb by mass. The lower limit of the metal content is not particularly limited and is preferably 0.

Exemplary methods of reducing the metal content include a refining treatment, such as distillation or filtration using ion-exchange resin or a filter, that is carried out in a stage of raw materials to be used in manufacture of the cleaning liquid or a stage after manufacture of the cleaning liquid.

Another method of reducing the metal content is the one using, as a container storing a raw material or the manufactured cleaning liquid, a container from which impurities are not largely leached, which will be described later. Still another method is providing lining of fluororesin on inner walls of pipes used in manufacture of the cleaning liquid in order to prevent metal components from being leached from the pipes and the like.

### <Coarse Particles>

The cleaning liquid may contain coarse particles but preferably in a small amount. The coarse particles herein refer to particles with a diameter (particle size) of not less than 0.4 μm when the particle shape is assumed to be a sphere.

For the coarse particle content of the cleaning liquid, the content of particles with a particle size of not less than 0.4 μm is preferably not more than 1000 particles and more preferably not more than 500 particles per milliliter of the cleaning liquid. The lower limit thereof is not particularly limited and is preferably 0. The content of particles with a particle size of not less than 0.4 μm measured by one of the foregoing measurement methods is even more preferably at or below the detection limit.

The coarse particles contained in the cleaning liquid are particles of dust, dirt, organic and inorganic solid matter, and the like contained as impurities in raw materials and particles of dust, dirt, organic and inorganic solid matter, and the like entering as contaminations during preparation of the cleaning liquid, which particles remain present as particles in the cleaning liquid at the end without being dissolved.

The content of the coarse particles present in the cleaning liquid can be measured in a liquid phase with a commercial measurement device for a light scattering liquid-borne particle counting method using a laser as a light source.

One exemplary method of removing the coarse particles is a refining treatment such as filtration to be described later.

The cleaning liquid may take the form of a kit including raw materials of the cleaning liquid that are separated into plural units.

One exemplary method of having the cleaning liquid in the form of a kit involves preparing a liquid composition containing a component A and a component B as a first liquid and preparing a liquid composition containing a component C and other components as a second liquid.

### [Manufacture of Cleaning Liquid]

The cleaning liquid can be manufactured by a known method. The method of manufacturing the cleaning liquid is described below in detail.

### <Liquid Preparation Step>

The method of preparing the cleaning liquid is not particularly limited, and for instance, the cleaning liquid can be manufactured by mixing the foregoing components. The order and/or timing of incorporating the foregoing components are not particularly limited. For instance, the amine compound Y0, the amine compound Z, the chelating agent, and/or the anticorrosive are sequentially added into a vessel containing purified pure water and then stirred and mixed, while the pH adjuster is added into the vessel to adjust the pH of the mixture solution, thereby preparing the cleaning liquid. When added to the vessel, water and those components may be added at one time or may be divided into plural portions and separately added.

A stirrer and a stirring method used in preparation of the cleaning liquid are not particularly limited, and a known device may be used as the stirrer or a disperser. Examples of the stirrer include an industrial mixer, a portable stirrer, a mechanical stirrer, and a magnetic stirrer. Examples of the disperser include an industrial disperser, a homogenizer, an ultrasonic disperser, and a bead mill.

Mixing of the components in the preparation step of the cleaning liquid, a refining treatment to be described later, and storage of the manufactured cleaning liquid are carried out at a temperature of preferably not higher than 40° C. and more preferably not higher than 30° C. At the same time, not lower than 5° C. is preferred, and not lower than 10° C. is more preferred. The preparation, the treatment and/or the storage of the cleaning liquid within the above temperature range makes it possible to maintain stable performance for a long period of time.

### (Refining Treatment)

One or more of raw materials used in preparation of the cleaning liquid is preferably subjected to a refining treatment in advance. The refining treatment is not particularly limited, and examples thereof include known methods such as distillation, ion exchange, and filtration.

The degree of refining is not particularly limited, and a raw material is refined to a purity of preferably not less than 99 mass % and more preferably not less than 99.9 mass %.

Examples of specific methods of the refining treatment include a method in which a raw material is passed through ion-exchange resin, a reverse osmosis membrane (RO membrane), or the like, distillation of a raw material, and filtration to be described later.

As the refining treatment, the foregoing refining methods may be used in combination of two or more. For instance, a raw material may be firstly subjected to primary refinement in which the material is passed through a RO membrane and then to secondary refinement in which the material is passed through a refinement device made of cation exchange resin, anion exchange resin, or mixed-bed ion exchange resin.

The refining treatment may be carried out plural times

### (Filtration)

A filter used in filtration is not particularly limited as long as it is of a type that has been conventionally used for filtration and like purposes. Examples of the filter include filters made of fluororesins such as polytetrafluoroethylene (PTFE) and tetrafluoroethylene-perfluoroalkylvinylether copolymer (PFA), polyamide resins such as nylon, and polyolefin resins (including high density ones and ultra-high molecular weight ones) such as polyethylene and polypropylene (PP). Preferred is a filter made of, of the above materials, a material selected from the group consisting of polyethylene, polypropylene (including high density polypropylene), fluororesin (including PTFE and PFA), and polyamide resin (including nylon), and more preferred is a filter made of fluororesin. By filtering a raw material with the filter made of such a material, foreign matter with high polarity that easily causes defects can be effectively removed.

The filter has a critical surface tension of preferably 70 to 95 mN/m and more preferably 75 to 85 mN/m. It should be noted that the value of the critical surface tension of the filter is a nominal value provided by its manufacturer. The use of the filter having a critical surface tension within the above range makes it possible to effectively remove foreign matter with high polarity that easily causes defects.

The filter has a pore size of preferably 2 to 20 nm and more preferably 2 to 15 nm. The pore size within the above range makes it possible to reliably remove fine foreign matter such as impurities and agglomerates contained in a raw material, while preventing clogging in filtration. The pore size herein can be determined by reference to a nominal value of the relevant filter manufacturer.

Filtration may be carried out only one time or two or more times. When filtration is carried out two or more times, the filters used may be the same or different.

Filtration is carried out preferably at room temperature (25° C.) or lower, more preferably at 23° C. or lower, and even more preferably at 20° C. or lower, and at the same time, preferably at 0° C. or higher, more preferably at 5° C. or higher, and even more preferably at 10° C. or higher. Filtration at a temperature within the foregoing range makes it possible to reduce the amounts of particulate foreign matter and impurities dissolved in a raw material and effectively remove foreign matter and impurities.

### (Container)

The cleaning liquid (including an embodiment of a kit or a diluted solution to be described later) can be put into a given container and stored, transported and used as long as problems such as corrosion do not occur.

For the container, preferred is a container which has high cleanliness in its interior and in which leaching of impurities from the inner wall of a storage portion of the container to the liquid is suppressed, for semiconductor applications. Examples of such a container include various containers commercially available as containers for semiconductor cleaning liquids, as exemplified by, but not limited to, the “Clean Bottle” series manufactured by Aicello Corporation and “Pure Bottle” manufactured by Kodama Plastics Co., Ltd.

For the container storing the cleaning liquid, preferred is a container whose portion to contact the liquid, such as the inner wall of its storage portion, is formed from fluororesin (perfluororesin) or metal having undergone a rust proof and metal leaching prevention treatment.

The inner wall of the container is preferably formed from one or more resins selected from the group consisting of polyethylene resin, polypropylene resin, and polyethylene-polypropylene resin, or another resin different therefrom, or a metal having undergone a rust proof and metal leaching prevention treatment such as stainless steel, Hastelloy, Inconel, or Monel.

For another resin above, fluororesin (perfluororesin) is preferred. When such a container with its inner wall being formed from fluororesin is used, defects such as leaching of oligomers of ethylene or propylene can be suppressed as compared to a container with its inner wall being formed from polyethylene resin, polypropylene resin, or polyethylene-polypropylene resin.

Specific examples of such a container with its inner wall being formed from fluororesin include FluoroPure PFA composite drums manufactured by Entegris, Inc. In addition, the containers described in page 4 of JP 3-502677 A, page 3 of the description of WO 2004/016526, and pages 9 and 16, among other pages, of the description of WO 99/046309 may also be used.

In addition to the foregoing fluororesin, quartz and an electrolytically polished metal material (i.e., a metal material having undergone electrolytic polishing) may also be preferably used for the inner wall of the container.

For a metal material used in manufacture of the foregoing electrolytically polished metal material, preferred is a metal material containing at least one selected from the group consisting of chromium and nickel, with the total content of chromium and nickel being more than 25 mass % based on the total mass of the metal material. Examples of such a metal material include stainless steel and a nickel-chromium alloy.

The total content of chromium and nickel in the metal material is more preferably not less than 30 mass % based on the total mass of the metal material.

The upper limit of the total content of chromium and nickel in the metal material is not particularly limited. Generally, the upper limit of the total content thereof is preferably not more than 90 mass %.

The method of electrolytic polishing of the metal material is not particularly limited, and any known methods may be used. For instance, the methods described in paragraphs [0011] to

of JP 2015-227501 A and paragraphs [0036] to [0042] of JP 2008-264929 A may be used (the contents thereof are incorporated in this specification).

Preferably, the inside of the containers is washed before being filled with the cleaning liquid. For a liquid used for washing, the amount of metal impurities in the liquid is preferably reduced in advance. After being manufactured, the cleaning liquid may be bottled in such containers as gallon bottles or quart bottles, transported and stored.

In order to prevent the components in the cleaning liquid from changing during storage, the inside of each container may be replaced with an inert gas (nitrogen, argon or the like) having a purity of not less than 99.99995 vol % in advance. In particular, a gas with a low moisture content is preferred. While the transportation and the storage may be carried out at normal temperature, the temperature may be controlled to fall within the range of −20° C. to 20° C. to prevent the change of properties.

### (Cleanroom)

It is preferable to conduct all of manufacture of the cleaning liquid, opening and washing of the containers, handling of the cleaning liquid such as filling, process and treatment analyses, and measurements in a cleanroom. The cleanroom preferably satisfies ISO (International Organization for Standardization) 14644-1 cleanroom standards. The cleanroom satisfies preferably one of ISO Class 1, ISO Class 2, ISO Class 3, and ISO Class 4, more preferably ISO Class 1 or ISO Class 2, and even more preferably ISO Class 1.

### <Dilution Step>

The cleaning liquid as above may be subjected to a dilution step in which the liquid is diluted with a diluent such as water, and then used as a cleaning liquid (diluted cleaning liquid) to clean semiconductor substrates.

The dilution ratio of the cleaning liquid in the dilution step may be adjusted as appropriate depending on, for instance, the types and contents of the components and the type of semiconductor substrates to be cleaned. The ratio of the diluted cleaning liquid to the cleaning liquid before dilution (dilution factor) is preferably 10 to 10000 times, more preferably 20 to 3000 times, and even more preferably 50 to 1000 times in mass ratio or volume ratio (volume ratio at 23° C.)

The cleaning liquid is diluted preferably with water because this leads to more excellent defect suppression performance.

A preferable content of each component (excluding water) based on the total mass of the diluted cleaning liquid is, for instance, an amount obtained by dividing the amount described above as the preferable content of each component based on the total mass of the cleaning liquid (cleaning liquid before dilution) by the dilution factor (for instance, 100) in the above range.

The change in pH of the cleaning liquid from that before dilution to that after dilution (a difference between the pH of the cleaning liquid before dilution and that after dilution) is preferably not more than 1.0, more preferably not more than 0.8 and even more preferably not more than 0.5.

The pH of the diluted cleaning liquid is preferably 8.0 to 11.0 at 25° C.

A specific method of diluting the cleaning liquid in the dilution step is not particularly limited, and the dilution step may be carried out according to the liquid preparation step of the cleaning liquid described above. A stirrer and a stirring method used in the dilution step are also not particularly limited, and stirring may be carried out with a known stirrer whose examples are listed in the liquid preparation step of the cleaning liquid described above.

Water used in the dilution step is preferably subjected to a refining treatment in advance. Preferably, the diluted cleaning liquid obtained in the dilution step is also subjected to a refining treatment.

The refining treatment is not particularly limited, and examples thereof include an ionic component reduction treatment using ion-exchange resin, a RO membrane, or the like, and removal of foreign matter through filtration, which are described above as examples of the refining treatment for the cleaning liquid; preferably, one of these treatments is carried out.

### [Application of Cleaning Liquid]

The cleaning liquid is used in a cleaning step of cleaning a semiconductor substrate having undergone a chemical mechanical polishing (CMP) process. The cleaning liquid also can be used in cleaning of a semiconductor substrate in a semiconductor substrate manufacturing process.

As described above, the diluted cleaning liquid obtained by diluting the cleaning liquid may be used in cleaning of semiconductor substrates.

### [Cleaning Object]

One example of a cleaning object to be cleaned with the cleaning liquid is a semiconductor substrate having metal-containing matter.

The expression “on a semiconductor substrate” in this specification includes places on the top, bottom and lateral sides of the semiconductor substrate and in a groove or any other part of the semiconductor substrate. The metal-containing matter on a semiconductor substrate includes not only metal-containing matter present directly on a surface of the semiconductor substrate but also metal-containing matter present on or above the semiconductor substrate via another layer.

A metal contained in the metal-containing matter is for instance at least one metal M selected from the group consisting of Cu (copper), Co (cobalt), W (tungsten), Ti (titanium), Ta (tantalum), Ru (ruthenium), Cr (chromium), Hf (hafnium), Os (osmium), Pt (platinum), Ni (nickel), Mn (manganese), Zr (zirconium), Mo (molybdenum), La (lanthanum), and Ir (iridium).

The metal-containing matter is not limited as long as it is a substance containing metal (metallic atom), and examples thereof include a simple substance of the metal M, an alloy containing the metal M, an oxide of the metal M, a nitride of the metal M, and an oxynitride of the metal M.

The metal-containing matter may be a mixture containing two or more of those compounds.

The oxide, the nitride and the oxynitride above may be a composite oxide, a composite nitride and a composite oxynitride each of which contains metal.

The metallic atom content of the metal-containing matter is preferably not less than 10 mass %, more preferably not less than 30 mass % and even more preferably not less than 50 mass % based on the total mass of the metal-containing matter. The upper limit thereof is 100 mass % because the metal-containing matter may be exactly the metal itself.

The semiconductor substrate has preferably metal M-containing matter, which contains the metal M, more preferably the metal-containing matter containing at least one metal selected from the group consisting of Cu, Co, W, Ti, Ta, and Ru (such as copper-containing matter, cobalt-containing matter, tungsten-containing matter, titanium-containing matter, tantalum-containing matter, and ruthenium-containing matter), and even more preferably the metal-containing matter containing at least one metal selected from the group consisting of Cu, Co, and W.

The semiconductor substrate that is a cleaning object to be cleaned with the cleaning liquid is not particularly limited, and examples thereof include one having a metal wiring film, a barrier metal, and an insulating film on a surface of a wafer constituting the semiconductor substrate.

Specific examples of the wafer constituting the semiconductor substrate include wafers made of silicon-based materials such as a silicon (Si) wafer, a silicon carbide (SiC) wafer, and a silicon-containing resin wafer (glass epoxy wafer), a gallium phosphide (GaP) wafer, a gallium arsenide (GaAs) wafer, and an indium phosphide (InP) wafer.

Applicable examples of the silicon wafer include an n-type silicon wafer in which a silicon wafer is doped with a pentavalent atom (e.g., phosphorus (P), arsenic (As), and antimony (Sb)), and a p-type silicon wafer in which a silicon wafer is doped with a trivalent atom (e.g., boron (B), and gallium (Ga)). Silicon of the silicon wafer may be any of, for example, amorphous silicon, monocrystalline silicon, polycrystalline silicon, and polysilicon.

In particular, the cleaning liquid is useful for wafers made of silicon-based materials such as a silicon wafer, a silicon carbide wafer, and a silicon-containing resin wafer (glass epoxy wafer).

The semiconductor substrate may have an insulating film on the wafer described above.

Specific examples of the insulating film include silicon oxide films (e.g., a silicon dioxide (SiO₂) film and a tetraethyl orthosilicate (Si(OC₂H₅)₄) film (TEOS film)), silicon nitride films (e.g., a silicon nitride (Si₃N₄) film and a silicon nitride/carbide (SiNC) film), and low dielectric (Low-k) films (e.g., a carbon-doped silicon oxide (SiOC) film and a silicon carbide (SiC) film).

The metal-containing matter is also preferably a metal-containing film.

Examples of a metal film that the semiconductor substrate has include a metal film containing at least one metal selected from the group consisting of copper (Cu), cobalt (Co), and tungsten (W). Specific examples thereof include a film primarily composed of copper (copper-containing film), a film primarily composed of cobalt (cobalt-containing film), a film primarily composed of tungsten (tungsten-containing film), and a metal film constituted of an alloy including one or more selected from the group consisting of Cu, Co and W.

The semiconductor substrate preferably has a metal film containing cobalt. The semiconductor substrate also preferably has a metal film containing copper or tungsten.

Examples of the copper-containing film include a wiring film composed only of metallic copper (copper wiring film) and a wiring film made of an alloy composed of metallic copper and other metals (copper alloy wiring film).

Specific examples of the copper alloy wiring film include a wiring film made of an alloy composed of copper and one or more metals selected from aluminum (Al), titanium (Ti), chromium (Cr), manganese (Mn), tantalum (Ta) and tungsten (W). More specifically, examples thereof include a copper-aluminum alloy wiring film (CuAl alloy wiring film), a copper-titanium alloy wiring film (CuTi alloy wiring film), a copper-chromium alloy wiring film (CuCr alloy wiring film), a copper-manganese alloy wiring film (CuMn alloy wiring film), a copper-tantalum alloy wiring film (CuTa alloy wiring film), and a copper-tungsten alloy wiring film (CuW alloy wiring film).

Examples of the cobalt-containing film (a metal film primarily composed of cobalt) include a metal film composed only of metallic cobalt (cobalt metal film) and a metal film made of an alloy composed of metallic cobalt and other metals (cobalt alloy metal film).

Specific examples of the cobalt alloy metal film include a metal film made of an alloy composed of cobalt and one or more metals selected from titanium (Ti), chromium (Cr), iron (Fe), nickel (Ni), molybdenum (Mo), palladium (Pd), tantalum (Ta) and tungsten (W). More specifically, examples thereof include a cobalt-titanium alloy metal film (CoTi alloy metal film), a cobalt-chromium alloy metal film (CoCr alloy metal film), a cobalt-iron alloy metal film (CoFe alloy metal film), a cobalt-nickel alloy metal film (CoNi alloy metal film), a cobalt-molybdenum alloy metal film (CoMo alloy metal film), a cobalt-palladium alloy metal film (CoPd alloy metal film), a cobalt-tantalum alloy metal film (CoTa alloy metal film), and a cobalt-tungsten alloy metal film (CoW alloy metal film).

The cleaning liquid is useful for a substrate having the cobalt-containing film. Of the cobalt-containing films, the cobalt metal film is often used as a wiring film, and the cobalt alloy metal film is often used as a barrier metal.

In some cases, it is preferable to use the cleaning liquid in cleaning of the semiconductor substrate having at least the copper-containing wiring film and the metal film (cobalt barrier metal), which is composed only of metallic cobalt and is a barrier metal of the copper-containing wiring film, on or above the wafer constituting the substrate, with the copper-containing wiring film and the cobalt barrier metal being in contact with each other at a surface of the substrate.

Examples of the tungsten-containing film (a metal film primarily composed of tungsten) include a metal film composed only of tungsten (tungsten metal film) and a metal film made of an alloy composed of tungsten and other metals (tungsten alloy metal film).

Specific examples of the tungsten alloy metal film include a tungsten-titanium alloy metal film (WTi alloy metal film) and a tungsten-cobalt alloy metal film (WCo alloy metal film).

Generally, the tungsten-containing film is often used as a barrier metal.

The methods of forming the foregoing insulating film, copper-containing wiring film, cobalt-containing film and tungsten-containing film on the wafer constituting the semiconductor substrate are not particularly limited as long as they are methods commonly used in this field.

One exemplary method of forming the insulating film is a method in which the wafer constituting the semiconductor substrate is subjected to a heating treatment in the presence of oxygen gas to form a silicon oxide film, whereafter silane and ammonia gases are introduced to form a silicon nitride film by a chemical vapor deposition (CVD) method.

Exemplary methods of forming the copper-containing wiring film, the cobalt-containing film and the tungsten-containing film include a method in which a circuit is formed on the wafer having the above insulating film by a known method using a resist for instance, whereafter the copper-containing wiring film, the cobalt-containing film, or the tungsten-containing film is formed by plating, the CVD method, or another method.

### <CMP Process>

The CMP process is, for instance, a process for planarizing a surface of the substrate having the metal wiring film, the barrier metal and the insulating film through a combination of a chemical action induced by use of a polishing slurry containing fine abrasive particles (abrasive grains) and mechanical polishing.

Abrasive grains (e.g., silica and alumina) used in the CMP process, metal impurities (metal residues) derived from the polished metal wiring film and barrier metal, and other impurities sometimes remain on the surface of the semiconductor substrate having undergone the CMP process. These impurities may cause short circuit between wirings and adversely affect electric characteristics of the semiconductor substrate; therefore, the semiconductor substrate having undergone the CMP process is subjected to a cleaning treatment to remove these impurities from the surface of the semiconductor substrate.

Specific examples of the semiconductor substrate having undergone the CMP process include but not limited to a substrate having undergone the CMP process described in Journal of the Japan Society for Precision Engineering, Vol. 84, No. 3, 2018.

### <Buffing Process>

The surface of the semiconductor substrate, which is an object to be cleaned with the cleaning liquid, may be subjected to a buffing process after undergoing to the CMP process.

The buffing process is a process of reducing impurities on the surface of the semiconductor substrate using a polishing pad. Specifically, the surface of the semiconductor substrate having undergone the CMP process is brought into contact with a polishing pad. Then, the semiconductor substrate and the polishing pad are slid with respect to each other while a buffing composition is being supplied to the portion of contact between the semiconductor substrate and the polishing pad. As a result, the impurities on the surface of the semiconductor substrate are removed by frictional force of the polishing pad and a chemical action of the buffing composition.

For the buffing composition, it is possible to use a known buffing composition as appropriate depending on the type of the semiconductor substrate and the types and amounts of impurities to be removed. The components contained in the buffing composition are not particularly limited, and examples thereof include water-soluble polymers such as polyvinyl alcohol, water as a dispersion medium, and acids such as nitric acid.

In one embodiment of the buffing process, it is preferable to perform the buffing process on the semiconductor substrate by using the above-described cleaning liquid as the buffing composition.

A polishing apparatus, polishing conditions, and other factors employed in the buffing process may be selected conveniently from known apparatuses and conditions depending on the type of the semiconductor substrate, the object to be removed, and other situations. Examples of the buffing process include the process described in paragraphs [0085] to [0088] of WO 2017/169539, and the contents thereof are incorporated in this specification.

### [Method of Cleaning Semiconductor Substrates]

The method of cleaning semiconductor substrates is not particularly limited as long as it includes a cleaning step of cleaning the semiconductor substrate having undergone the CMP process by use of the foregoing cleaning liquid. It is preferable that the method of cleaning semiconductor substrates include a cleaning step in which the diluted cleaning liquid obtained in the foregoing dilution step is applied to the semiconductor substrate having undergone the CMP process to thereby clean the semiconductor substrate.

The cleaning step of cleaning the semiconductor substrate with the cleaning liquid is not particularly limited as long as it is a known method used for semiconductor substrates having undergone the CMP process, and any of methods commonly carried out in this field may be suitably applied, as exemplified by brush scrubbing cleaning that, while supplying the cleaning liquid to the semiconductor substrate, brings a cleaning member such as a brush into physical contact with a surface of the semiconductor substrate to remove residues or the like, an immersion method in which the semiconductor substrate is immersed in the cleaning liquid, a spinning (dropping) method in which the cleaning liquid is dropped while the semiconductor substrate is rotated, or a spraying method in which the cleaning liquid is sprayed. In cleaning by the immersion method, the cleaning liquid having the semiconductor substrate immersed therein is preferably subjected to an ultrasonic treatment because this can further reduce impurities remaining on the surface of the semiconductor substrate.

The cleaning step may be carried out only one time or two or more times. When the cleaning step is carried out two or more times, the same method may be repeated or different methods may be combined.

For the method of cleaning semiconductor substrates, any of a single wafer process and a batch process may be employed. The single wafer process is generally a method in which semiconductor substrates are treated one by one, while the batch process is generally a method in which a plurality of semiconductor substrates are treated at one time.

The temperature of the cleaning liquid used in cleaning of the semiconductor substrate is not particularly limited as long as it is the temperature commonly employed in this field. While cleaning is generally carried out at room temperature (about 25° C.), the temperature can be arbitrarily selected in view of improvement in cleaning properties and suppression of damage to a member. For instance, the temperature of the cleaning liquid is preferably 10° C. to 60° C. and more preferably 15° C. to 50° C.

The cleaning time in cleaning of the semiconductor substrate depends on, for instance, the types and the contents of components contained in the cleaning liquid, and therefore cannot be unconditionally stated; practically, the cleaning time is preferably 10 seconds to 2 minutes, more preferably 20 seconds to 1 minute and 30 seconds, and even more preferably 30 seconds to 1 minute.

The amount of supply (feed rate) of the cleaning liquid in the cleaning step of the semiconductor substrate is not particularly limited and is preferably 50 to 5000 mL/min and more preferably 500 to 2000 mL/min.

In cleaning of the semiconductor substrate, a mechanical stirring method may be used to further enhance the cleaning ability of the cleaning liquid.

Examples of the mechanical stirring method include a method involving circulating the cleaning liquid on the semiconductor substrate, a method involving flowing or spraying the cleaning liquid on the semiconductor substrate, and a method involving stirring the cleaning liquid by ultrasonics or megasonics.

The cleaning of the semiconductor substrate may be followed by a step of rinsing and washing the semiconductor substrate with a solvent (hereinafter called “rinsing step”).

The rinsing step is preferably a step that consecutively follows the cleaning step of the semiconductor substrate and that is carried out with a rinsing solvent (rinsing liquid) for 5 seconds to 5 minutes. The rinsing step may be carried out using the mechanical stirring method as above.

Examples of the rinsing solvent include water (preferably deionized (DI) water), methanol, ethanol, isopropyl alcohol, N-methylpyrrolidinone, γ-butyrolactone, dimethyl sulfoxide, ethyl lactate, and propylene glycol monomethyl ether acetate. Alternatively, an aqueous rinsing liquid with a pH of more than 8 (e.g., a diluted aqueous ammonium hydroxide) may be used.

The forgoing method of bringing the cleaning liquid into contact with the semiconductor substrate is applicable as a method of bringing the rinsing solvent into contact with the semiconductor substrate in the same manner.

The rinsing step may be followed by a drying step for drying the semiconductor substrate.

The drying method is not particularly limited, and examples thereof include spin drying, a method involving flowing dry gas on the semiconductor substrate, a method involving heating the substrate by a heating means such as a hot plate or an infrared lamp, Marangoni drying, Rotagoni drying, isopropyl alcohol (IPA) drying, and any combinations thereof.

### EXAMPLES

The present invention is described below in further detail based on examples. The materials, amounts of use, ratios and other factors illustrated in examples below may be suitably modified as long as they do not depart from the scope and spirit of the present invention. Therefore, the scope of the present invention should not be construed as being limited to the examples below.

In the examples below, the pH values of cleaning liquids were measured at 25° C. with a pH meter (type: F-74, manufactured by HORIBA, Ltd.) according to JIS Z 8802-1984.

In manufacture of cleaning liquids of Examples and Comparative Examples, handling of containers and preparation, filling, storage, analysis and measurement of the cleaning liquids were all conducted in a cleanroom with the level satisfying ISO Class 2 or lower class. In measurement of the metal content of a cleaning liquid, when the content of a substance at or below the detection limit was measured in normal measurement, the measurement was carried out after the cleaning liquid was concentrated to 1/100 in terms of volume, and the measurement result was converted into a value of the metal content of the liquid at the concentration before the liquid was concentrated, in order to improve the measurement accuracy.

### [Raw Materials of Cleaning Liquid]

The following compounds were used to manufacture the cleaning liquids. It should be noted that all the various components used in Examples were those classified as Semiconductor Grade or a high-purity grade equivalent to Semiconductor Grade.

### [Amine Compound Y0]

N,N′-Bis(3-aminopropyl)ethylenediamine: manufactured by FUJIFILM Wako Pure Chemical Corporation, corresponding to the amine compound Y0
1,4-Butanediamine: manufactured by FUJIFILM Wako Pure Chemical Corporation, corresponding to the amine compound Y0
2,6,10-Trimethyl-2,6,10-triazaundecane: manufactured by FUJIFILM Wako Pure Chemical Corporation, corresponding to the amine compound Y0
1,4-Bis(3-aminopropyl)piperidine: manufactured by FUJIFILM Wako Pure Chemical Corporation, corresponding to the amine compound Y0
1-(3-Aminopropyl)-2-methylpiperidine: manufactured by FUJIFILM Wako Pure Chemical Corporation, corresponding to the amine compound Y0
1-(3-Aminopropyl)imidazole: manufactured by FUJIFILM Wako Pure Chemical Corporation, corresponding to the amine compound Y0
2,2-Dimethyl-1,3-propanediamine: manufactured by FUJIFILM Wako Pure Chemical Corporation, corresponding to the amine compound Y0
N,N-Dimethyl-1,3-propanediamine: manufactured by FUJIFILM Wako Pure Chemical Corporation, corresponding to the amine compound Y0
N-Methyl-1,3-diaminopropane: manufactured by FUJIFILM Wako Pure Chemical Corporation, corresponding to the amine compound Y0
3,3′-Diamino-N-methyldipropylamine: manufactured by FUJIFILM Wako Pure Chemical Corporation, corresponding to the amine compound Y0
3,3′-Diaminodipropylamine: manufactured by FUJIFILM Wako Pure Chemical Corporation, corresponding to the amine compound Y0
N,N-Diethyl-1,3-diaminopropane: manufactured by FUJIFILM Wako Pure Chemical Corporation, corresponding to the amine compound Y0
N,N,2,2-Tetramethyl-1,3-propanediamine: manufactured by FUJIFILM Wako Pure Chemical Corporation, corresponding to the amine compound Y0
3-(Dibutylamino)propylamine: manufactured by FUJIFILM Wako Pure Chemical Corporation, corresponding to the amine compound Y0
N,N,N′,N′-Tetramethyl-1,3-diaminopropane: manufactured by FUJIFILM Wako Pure Chemical Corporation, corresponding to the amine compound Y0
N-(3-Aminopropyl)diethanolamine: manufactured by FUJIFILM Wako Pure Chemical Corporation, corresponding to the amine compound Y0
N-(3-Aminopropyl)cyclohexylamine: manufactured by FUJIFILM Wako Pure Chemical Corporation, corresponding to the amine compound Y0
N3-Amine 3-(2-aminoethylamino)propylamine: manufactured by FUJIFILM Wako Pure Chemical Corporation, corresponding to the amine compound Y0
N4-Amine-N,N′-bis(3-aminopropyl)ethylenediamine: manufactured by FUJIFILM Wako Pure Chemical Corporation, corresponding to the amine compound Y0

### [Chelating Agent]

Diethylenetriaminepentaacetic acid (DTPA): manufactured by Fujifilm Wako Pure Chemical Corporation
Adipic acid: manufactured by Fujifilm Wako Pure Chemical Corporation

### [Amine Compound Z]

2-Amino-2-methyl-1-propanol (AMP): manufactured by Fujifilm Wako Pure Chemical Corporation
Monoethanolamine (MEA): manufactured by Fujifilm Wako Pure Chemical Corporation
Diethanolamine (DEA): manufactured by Fujifilm Wako Pure Chemical Corporation
2-(Aminoethoxy)ethanol (AEE): manufactured by Fujifilm Wako Pure Chemical Corporation
Tetraethylammonium hydroxide (TEAH): manufactured by Fujifilm Wako Pure Chemical Corporation
Methyltriethylammonium hydroxide (MTEAH): manufactured by Fujifilm Wako Pure Chemical Corporation
1,3-Propanediamine: manufactured by Fujifilm Wako Pure Chemical Corporation
3-Morpholinopropylamine: manufactured by Fujifilm Wako Pure Chemical Corporation

### [Anticorrosive]

N,N-Diethylhydroxylamine (DEHA): manufactured by Fujifilm Wako Pure Chemical Corporation
Ascorbic acid: manufactured by Fujifilm Wako Pure Chemical Corporation
Adenine: manufactured by Fujifilm Wako Pure Chemical Corporation
Pyrazole: manufactured by Fujifilm Wako Pure Chemical Corporation
3-Amino-5-methylpyrazole: manufactured by Fujifilm Wako Pure Chemical Corporation
Chlorhexidine gluconate (CHG): manufactured by Fujifilm Wako Pure Chemical Corporation
Gluconic acid: manufactured by Fujifilm Wako Pure Chemical Corporation
Citric acid: manufactured by Fujifilm Wako Pure Chemical Corporation
Cysteine: manufactured by Fujifilm Wako Pure Chemical Corporation

In the step of manufacturing the cleaning liquids in the examples, one of potassium hydrate (KOH) and sulfuric acid (H₂SO₄), and commercially available ultrapure water (manufactured by FUJIFILM Wako Pure Chemical Corporation) were used as the pH adjuster.

It should be noted that the content of the pH adjuster (potassium hydroxide or sulfuric acid) was not more than 2 mass % based on the total mass of the cleaning liquid in each of Examples and Comparative Examples.

### [Manufacture of Cleaning Liquid]

Next, a method of manufacturing a cleaning liquid is described taking Example 1 as an example.

To ultrapure water, N,N′-bis(3-aminopropyl)ethylenediamine, 2-amino-2-methyl-1-propanol (AMP), and N,N-diethylhydroxylamine (DEHA) were added in respective amounts such that the finally obtained cleaning liquid had the composition shown in Table 1-1. Then, the pH adjuster was added to the resulting mixture so that the pH of the prepared cleaning liquid was 10.5. The resulting mixture was sufficiently stirred with a stirrer, thereby obtaining a cleaning liquid of Example 1.

Cleaning liquids of Examples and Comparative Examples with the compositions shown in Tables 1-1 and 1-2 were manufactured according to the manufacturing method of Example 1.

### [Measurement of Metal Content]

The metal contents of the cleaning liquids prepared in Examples and Comparative Examples were measured.

Each metal content was measured using an Agilent 8800 triple quadrupole ICP-MS (for semiconductor analysis, option #200) under the following measurement conditions.

### (Measurement Conditions)

A quartz torch, a coaxial PFA nebulizer (self-priming), and a platinum interface cone were used as a sample introduction system. Measurement parameters of cool plasma conditions are as follows.
RF (Radio Frequency) output (W): 600
Carrier gas flow rate (L/min): 0.7
Make-up gas flow rate (L/min): 1
Sampling depth (mm): 18

In the measurement of the metal content, the metal particles and the metal ions were not distinguished from each other. Instead, the contents of the metal particles and the metal ions were summed up. When two or more metals were detected, the total content of the two or more metals was obtained.

### [Evaluation of Cleaning Performance]

Evaluation was made on cleaning performance (residue removal performance) when a metal film having undergone chemical mechanical polishing was cleaned using each of the cleaning liquids manufactured by the foregoing method.

The cleaning liquid of each of Examples and Comparative Examples was taken in an amount of 1 mL and diluted with ultrapure water by a factor of 100 to prepare a sample of a diluted cleaning liquid.

A wafer (diameter: 8 inches) having on its surface a metal film made of copper, tungsten, or cobalt was polished with FREX300S-II (a polishing apparatus, manufactured by Ebara Corporation). A wafer having a copper-made metal film on a surface was polished with polishing slurry, namely, CSL9044C and BSL8176C (commercial names, both manufactured by FUJIFILM Planar Solutions LLC.). This was for the purpose of eliminating or minimizing variation in cleaning performance evaluation caused by polishing slurry. Similarly, a wafer having a cobalt-made metal film on a surface was polished with polishing slurry, namely, CSL5340C and CSL5250C (commercial names, both manufactured by FUJIFILM Planar Solutions LLC.). A wafer having a tungsten-made metal film on a surface was polished only with W-2000 (commercial name, manufactured by Cabot Corporation). The polishing pressure was 2.0 psi, and the feed rate of the polishing slurry was 0.28 mL/(min·cm²). The polishing time was 60 seconds.

Thereafter, the polished wafer was cleaned for 1 minute by use of the sample of each diluted cleaning liquid whose temperature was adjusted to room temperature (23° C.), followed by drying.

The number of defects corresponding to a sensitivity intensity of at least 0.1 μm at a polished surface of the obtained wafer was detected with a defect detection apparatus (ComPlus-II, manufactured by Applied Materials, Inc.), and the cleaning liquid was evaluated for the cleaning performance according to the following evaluation criteria. The evaluation results are shown in Tables 1-1 and 1-2. As a wafer has a smaller number of defects caused by residues detected on the polished surface of the wafer, the cleaning liquid can be evaluated as being greater in excellence in cleaning performance.
“A”: The number of defects per wafer being less than 200
“B”: The number of defects per wafer being not less than 200 and less than 300
“C”: The number of defects per wafer being not less than 300 and less than 500
“D”: The number of defects per wafer being not less than 500

### [Evaluation of Corrosion Prevention Performance]

The cleaning liquid of each of Examples and Comparative Examples was taken in an amount of 0.02 mL and diluted with ultrapure water by a factor of 100 to prepare a sample of a diluted cleaning liquid.

A wafer (diameter: 12 inches) having on its surface a metal film made of copper, tungsten, or cobalt was cut to prepare a 2 cm by 2 cm wafer coupon. The thickness of each metal film was 200 nm. The wafer coupon was immersed in the sample of the diluted cleaning liquid (having a temperature of 23° C.) manufactured by the above-described method, and was subjected to an immersion treatment for 3 minutes at a stirring rotation speed of 250 rpm. For each metal film, the content of copper, tungsten, or cobalt in each diluted cleaning liquid was measured before and after the immersion treatment. From the measurement results obtained, corrosion rate per unit time (unit: A/min) was calculated. The corrosion prevention performance of the cleaning liquid was evaluated according to the following evaluation criteria. The results are shown in Tables 1-1 and 1-2.

As the corrosion rate is lower, the cleaning liquid is greater in excellence in the corrosion prevention performance.
“A”: The corrosion rate being less than 0.5 Å/min
“B”: The corrosion rate being not less than 0.5 Å/min and less than 1.0 Å/min
“C”: The corrosion rate being not less than 1.0 Å/min and less than 3.0 Å/min
“D”: The corrosion rate being not less than 3.0 Å/min

### [Results]

Tables 1-1 and 1-2 below show the compositions of the cleaning liquids of Examples and Comparative Examples. Tables 2-1 and 2-2 below show characteristics of the cleaning liquids of Examples and Comparative Examples and the results of the tests.

In Tables, the “Amount (%)” column indicates the content of each component based on the total mass of the cleaning liquid (unit: mass %).

In the “Amount” column of “pH adjuster”, “*1” means that H₂SO₄ or KOH was added in such an amount that the pH of the cleaning liquid to be prepared was the numerical value in the “pH” column.

The numerical values in the “pH” column each indicate the pH of the cleaning liquid at 25° C. measured with the above-described pH meter.

The “Metal content (ppb)” column indicates the measurement result of the metal content (unit: ppb by mass). The expression “<10” indicates that the metal content of the cleaning liquid was less than 10 ppb by mass based on the total mass of the cleaning liquid.

It should be noted that a component (remainder) which is not explicitly shown in Tables as a component of the cleaning liquid is water.

The “pka” column indicates first acid dissociation constant of the amine compound Z.

The “Ratio 1” column indicates the mass ratio of the content of the amine compound Y0 to the total content of the reducing sulfur compound and the hydroxycarboxylic acid in the cleaning liquid (the content of the amine compound Y0/the total content of the reducing sulfur compound and the hydroxycarboxylic acid).

The “Ratio 2” column indicates the mass ratio of the content of the amine compound Z to the content of the amine compound Y0 in the cleaning liquid (the content of the amine compound Z/the content of the amine compound Y0).

In Examples and Comparative Examples 1 to 4, the diluted cleaning liquid obtained by diluting the cleaning liquid by a factor of 100 had a pH in the range of 8.0 to 11.0. In Comparative Example 5, the diluted cleaning liquid obtained by diluting the cleaning liquid by a factor of 100 had a pH of more than 11.0 and not more than 12.0.

TABLE 1-1

| | | Composition of cleaning liquid | | | | | | | | | |
|---|---|---|---|---|---|---|---|---|---|---|---|
| | | | | | | Amine | | | | | |
| | | Amine compound Y0 | | Chelating agent | | (Amine compound Z) | | | Anticorrosive | | pH |
| | | | Amount | | Amount | | | Amount | | Amount | adjuster |
| | | Type | (%) | Type | (%) | Type | pKa | (%) | Type | (%) | Amount |
| Examples | 1 | N,N′-bis(3- | 0.2 | — | — | AMP | 9.7 | 6 | DEHA | 1.5 | *1 |
| | | aminopropyl)ethylenediamine | | | | | | | | | |
| | 2 | 1,4-butanediamine | 0.2 | — | — | AMP | 9.7 | 6 | DEHA | 1.5 | *1 |
| | 3 | N,N′-bis(3- | 0.2 | DTPA | 0.1 | AMP | 9.7 | 6 | DEHA | 1.5 | *1 |
| | | aminopropyl)ethylenediamine | | | | | | | | | |
| | 4 | 2,6,10-trimethyl-2,6,10- | 0.2 | — | — | AMP | 9.7 | 6 | DEHA | 1.5 | *1 |
| | | triazaundecane | | | | | | | | | |
| | 5 | 1,4-bis(3- | 0.2 | — | — | AMP | 9.7 | 6 | DEHA | 1.5 | *1 |
| | | aminopropyl)piperidine | | | | | | | | | |
| | 6 | 1-(3-aminopropyl)-2- | 0.2 | — | — | AMP | 9.7 | 6 | DEHA | 1.5 | *1 |
| | | methylpiperidine | | | | | | | | | |
| | 7 | 1-(3-aminopropyl)imidazole | 0.2 | — | — | AMP | 9.7 | 6 | DEHA | 1.5 | *1 |
| | 8 | 2,2-dimethyl-1,3-propanediamine | 0.2 | — | — | AMP | 9.7 | 6 | DEHA | 1.5 | *1 |
| | 9 | N,N-dimethyl-1,3-propanediamine | 0.2 | — | — | AMP | 9.7 | 6 | DEHA | 1.5 | *1 |
| | 10 | N-methyl-1,3-diaminopropane | 0.2 | — | — | AMP | 9.7 | 6 | DEHA | 1.5 | *1 |
| | 11 | 3,3′ -diamino-N-methyldipropylamine | 0.2 | — | — | AMP | 9.7 | 6 | DEHA | 1.5 | *1 |
| | 12 | 3,3′ -diaminodipropylamine | 0.2 | — | — | AMP | 9.7 | 6 | DEHA | 1.5 | *1 |
| | 13 | N,N-diethyl-1,3-diaminopropane | 0.2 | — | — | AMP | 9.7 | 6 | DEHA | 1.5 | *1 |
| | 14 | N,N,2,2-tetramethyl-1,3- | 0.2 | — | — | AMP | 9.7 | 6 | DEHA | 1.5 | *1 |
| | | propanediamine | | | | | | | | | |
| | 15 | 3-(dibutylamino)propylamine | 0.2 | — | — | AMP | 9.7 | 6 | DEHA | 1.5 | *1 |
| | 16 | N,N,N′,N′-tetramethyl-1,3- | 0.2 | — | — | AMP | 9.7 | 6 | DEHA | 1.5 | *1 |
| | | diaminopropane | | | | | | | | | |
| | 17 | N,N′-bis(3- | 0.2 | Adipic | 0.1 | AMP | 9.7 | 6 | DEHA | 1.5 | *1 |
| | | aminopropyl)ethylenediamine | | acid | | | | | | | |
| | 18 | N-(3-aminopropyl)diethanolamine | 0.2 | — | — | AMP | 9.7 | 6 | DEHA | 1.5 | *1 |
| | 19 | N-(3-aminopropyl)cyclohexylamine | 0.2 | — | — | AMP | 9.7 | 6 | DEHA | 1.5 | *1 |
| | 20 | N3-amine3-(2- | 0.2 | — | — | AMP | 9.7 | 6 | DEHA | 1.5 | *1 |
| | | aminoethylamino)propylamine | | | | | | | | | |
| | 21 | N4-amine-N,N′-bis(3- | 0.2 | — | — | AMP | 9.7 | 6 | DEHA | 1.5 | *1 |
| | | aminopropyl)ethylenediamine | | | | | | | | | |
| | 22 | N,N′-bis(3- | 0.01 | — | — | AMP | 9.7 | 6 | DEHA | 1.5 | *1 |
| | | aminopropyl)ethylenediamine | | | | | | | | | |
| | 23 | N,N′-bis(3- | 0.05 | — | — | AMP | 9.7 | 6 | DEHA | 1.5 | *1 |
| | | aminopropyl)ethylenediamine | | | | | | | | | |
| | 24 | N,N′-bis(3- | 0.3 | — | — | AMP | 9.7 | 6 | DEHA | 1.5 | *1 |
| | | aminopropyl)ethylenediamine | | | | | | | | | |
| | 25 | N,N′-bis(3- | 1 | — | — | AMP | 9.7 | 6 | DEHA | 1.5 | *1 |
| | | aminopropyl)ethylenediamine | | | | | | | | | |
| | 26 | N,N′-bis(3- | 3 | — | — | AMP | 9.7 | 6 | DEHA | 1.5 | *1 |
| | | aminopropyl)ethylenediamine | | | | | | | | | |
| | 27 | N,N′-bis(3- | 5 | — | — | AMP | 9.7 | 6 | DEHA | 1.5 | *1 |
| | | aminopropyl)ethylenediamine | | | | | | | | | |
| | 28 | N,N′-bis(3- | 12 | — | — | AMP | 9.7 | 6 | DEHA | 1.5 | *1 |
| | | aminopropyl)ethylenediamine | | | | | | | | | |

TABLE 1-2

| | | Composition of cleaning liquid | | | | | | | | |
|---|---|---|---|---|---|---|---|---|---|---|
| | | | | Chelating | | Amine | | | | |
| | | Amine compound Y0 | | agent | | (Amine compound Z) | | | Anticorrosive | |
| | | | Amount | | Amount | | | Amount | | Amount |
| | | Type | (%) | Type | (%) | Type | pKa | (%) | Type | (%) |
| Examples | 29 | N,N′-bis(3- | 0.2 | — | — | AMP | 9.7 | 6 | DEHA | 1.5 |
| | | aminopropyl)ethyl- | | | | MEA | 9.5 | 1 | | |
| | | enediamine | | | | | | | | |
| | 30 | N,N′-bis(3- | 0.2 | — | — | AMP | 9.7 | 6 | DEHA | 1.5 |
| | | aminopropyl)ethyl- | | | | DEA | 8.7 | 1 | | |
| | | enediamine | | | | | | | | |
| | 31 | N,N′-bis(3- | 0.2 | — | — | AMP | 9.7 | 6 | DEHA | 1.5 |
| | | aminopropyl)ethyl- | | | | AEE | 10.6 | 1 | | |
| | | enediamine | | | | | | | | |
| | 32 | N,N′-bis(3- | 0.2 | — | — | AMP | 9.7 | 6 | DEHA | 1.5 |
| | | aminopropyl)ethyl- | | | | TEAH | >14.0 | 1 | | |
| | | enediamine | | | | | | | | |
| | 33 | N,N′-bis(3- | 0.2 | — | — | AMP | 9.7 | 6 | DEHA | 1.5 |
| | | aminopropyl)ethyl- | | | | MTEA | >14.0 | 1 | | |
| | | enediamine | | | | | | | | |
| | 34 | N,N′-bis(3- | 0.2 | — | — | AMP | 9.7 | 6 | DEHA | 1.5 |
| | | aminopropyl)ethyl- | | | | | | | | |
| | | enediamine | | | | | | | | |
| | | 2,2-dimethyl-1,3- | 0.2 | | | | | | | |
| | | propanediamine | | | | | | | | |
| | 35 | N,N′-bis(3- | 0.2 | — | — | AMP | 9.7 | 6 | DEHA | 1.5 |
| | | aminopropyl)ethyl- | | | | | | | | |
| | | enediamine | | | | | | | | |
| | 36 | N,N′-bis(3- | 0.2 | — | — | AMP | 9.7 | 6 | DEHA | 1.5 |
| | | aminopropyl)ethyl- | | | | | | | | |
| | | enediamine | | | | | | | | |
| | 37 | N,N′-bis(3- | 0.2 | — | — | AMP | 9.7 | 6 | DEHA | 1.5 |
| | | aminopropyl)ethyl- | | | | | | | | |
| | | enediamine | | | | | | | | |
| | 38 | N,N′-bis(3- | 0.2 | — | — | AMP | 9.7 | 6 | DEHA | 0.75 |
| | | aminopropyl)ethyl- | | | | | | | Ascorbic | 0.75 |
| | | enediamine | | | | | | | acid | |
| | 39 | N,N′-bis(3- | 0.2 | — | — | AMP | 9.7 | 6 | DEHA | 1.5 |
| | | aminopropyl)ethyl- | | | | | | | | |
| | | enediamine | | | | | | | | |
| | 40 | N,N′-bis(3- | 0.2 | — | — | AMP | 9.7 | 6 | DEHA | 1.5 |
| | | aminopropyl)ethyl- | | | | | | | | |
| | | enediamine | | | | | | | | |
| | 41 | N,N′-bis(3- | 0.2 | — | — | AMP | 9.7 | 6 | DEHA | 1.5 |
| | | aminopropyl)ethyl- | | | | | | | | |
| | | enediamine | | | | | | | | |
| Comparative | 1 | — | — | — | — | MEA | 9.5 | 0.2 | DEHA | 1.5 |
| Examples | | | | | | AMP | 9.7 | 6 | | |
| | 2 | — | — | — | — | 1,3-propane- | 10.9 | 0.2 | DEHA | 1.5 |
| | | | | | | diamine | 9.7 | 6 | | |
| | | | | | | AMP | | | | |
| | 3 | — | — | — | — | 3-morpholino- | 10.3 | 0.2 | DEHA | 1.5 |
| | | | | | | propylamine | 9.7 | 6 | | |
| | | | | | | AMP | | | | |
| | 4 | — | — | — | — | AMP | 9.7 | 6 | DEHA | 1.5 |
| | 5 | N,N′-bis(3- | 0.2 | — | — | AMP | 9.7 | 6 | DEHA | 1.5 |
| | | aminopropyl)ethyl- | | | | | | | | |
| | | enediamine | | | | | | | | |

| | | Composition of cleaning liquid | | | | |
|---|---|---|---|---|---|---|
| | | Anticorrosive | | | | pH |
| | | | Amount | | Amount | adjuster |
| | | Type | (%) | Type | (%) | Amount |
| Examples | 29 | — | — | — | — | *1 |
| | 30 | — | — | — | — | *1 |
| | 31 | — | — | — | — | *1 |
| | 32 | — | — | — | — | *1 |
| | 33 | — | — | — | — | *1 |
| | 34 | — | — | — | — | *1 |
| | 35 | — | — | Gluconic acid | 2 | *1 |
| | 36 | — | — | Citric acid | 1 | *1 |
| | 37 | Adenine | 0.30 | Cysteine | 1 | *1 |
| | 38 | Pyrazole | 1.00 | Gluconic acid | 2 | *1 |
| | 39 | 3-amino-5-methylpyrazole | 0.30 | Gluconic acid | 0.1 | *1 |
| | 40 | CHG | 0.80 | Gluconic acid | 2 | *1 |
| | 41 | 3-amino-5-methylpyrazole | 0.40 | Gluconic acid | 0.5 | *1 |
| Comparative | | CHG | 0.40 | | | |
| Examples | 1 | — | — | — | — | *1 |
| | 2 | — | — | — | — | *1 |
| | 3 | — | — | — | — | *1 |
| | 4 | — | — | — | — | *1 |
| | 5 | — | — | — | — | *1 |

TABLE 2-1

| | | | | | | | | | Defect suppression | | |
|---|---|---|---|---|---|---|---|---|---|---|---|
| | | | | | | Defect suppression | | | performance | | |
| | | | | | | performance | | | Corrosion | | |
| | | | | | | Residue (cleaning | | | (Corrosion prevention | | |
| | | | Metal | | | performance) | | | performance) | | |
| | | | content | Ratio | Ratio | Polishing object | | | Polishing object | | |
| | | pH | (ppb) | 1 | 2 | Cu | W | Co | Cu | W | Co |
| Examples | 1 | 10.5 | <10 | — | 30 | B | B | B | B | B | B |
| | 2 | 10.5 | <10 | — | 30 | B | B | B | B | B | B |
| | 3 | 10.5 | <10 | — | 30 | A | A | A | B | B | B |
| | 4 | 10.5 | <10 | — | 30 | B | B | B | B | B | B |
| | 5 | 10.5 | <10 | — | 30 | B | B | B | B | B | B |
| | 6 | 10.5 | <10 | — | 30 | B | B | B | B | B | B |
| | 7 | 10.5 | <10 | — | 30 | B | B | B | B | B | B |
| | 8 | 10.5 | <10 | — | 30 | B | B | B | B | B | B |
| | 9 | 10.5 | <10 | — | 30 | B | B | B | B | B | B |
| | 10 | 10.5 | <10 | — | 30 | B | B | B | B | B | B |
| | 11 | 10.5 | <10 | — | 30 | B | B | B | B | B | B |
| | 12 | 10.5 | <10 | — | 30 | B | B | B | B | B | B |
| | 13 | 10.5 | <10 | — | 30 | B | B | B | B | B | B |
| | 14 | 10.5 | <10 | — | 30 | B | B | B | B | B | B |
| | 15 | 10.5 | <10 | — | 30 | B | B | B | B | B | B |
| | 16 | 10.5 | <10 | — | 30 | B | B | B | B | B | B |
| | 17 | 10.5 | <10 | — | 30 | A | A | A | A | A | A |
| | 18 | 10.5 | <10 | — | 30 | B | B | B | B | B | B |
| | 19 | 10.5 | <10 | — | 30 | B | B | B | B | B | B |
| | 20 | 10.5 | <10 | — | 30 | B | B | B | B | B | B |
| | 21 | 10.5 | <10 | — | 30 | B | B | B | B | B | B |
| | 22 | 10.5 | <10 | — | 600 | C | B | C | B | B | B |
| | 23 | 10.5 | <10 | — | 120 | B | B | C | B | B | B |
| | 24 | 10.5 | <10 | — | 20 | B | B | B | B | B | B |
| | 25 | 10.5 | <10 | — | 6 | B | B | B | B | B | B |
| | 26 | 10.5 | <10 | — | 2 | B | B | B | B | B | B |
| | 27 | 10.5 | <10 | — | 1.2 | A | B | B | B | B | C |
| | 28 | 10.5 | <10 | — | 0.5 | A | B | B | B | B | C |

TABLE 2-2

| | | | | | | | | | Defect suppression | | |
|---|---|---|---|---|---|---|---|---|---|---|---|
| | | | | | | Defect suppression | | | performance | | |
| | | | | | | performance | | | Corrosion | | |
| | | | | | | Residue (cleaning | | | (Corrosion prevention | | |
| | | | Metal | | | performance) | | | performance) | | |
| | | | content | Ratio | Ratio | Polishing object | | | Polishing object | | |
| | | pH | (ppb) | 1 | 2 | Cu | W | Co | Cu | W | Co |
| Examples | 29 | 10.5 | <10 | — | 35 | A | A | B | B | B | B |
| | 30 | 10.5 | <10 | — | 35 | A | A | B | B | B | B |
| | 31 | 10.5 | <10 | — | 35 | A | A | B | B | B | B |
| | 32 | 10.5 | <10 | — | 35 | A | A | B | B | B | B |
| | 33 | 10.5 | <10 | — | 35 | A | A | B | B | B | B |
| | 34 | 10.5 | <10 | — | 15 | A | A | A | B | B | B |
| | 35 | 10.5 | <10 | 0.1 | 30 | A | A | A | B | B | B |
| | 36 | 10.5 | <10 | 0.2 | 30 | A | A | A | B | B | B |
| | 37 | 10.5 | <10 | 0.2 | 30 | A | A | A | A | B | A |
| | 38 | 10.5 | <10 | 0.1 | 30 | A | A | A | B | B | A |
| | 39 | 10.5 | <10 | 2.0 | 30 | A | A | A | A | B | A |
| | 40 | 10.5 | <10 | 0.1 | 30 | A | A | A | B | A | B |
| | 41 | 10.5 | <10 | 0.4 | 30 | A | A | A | A | A | A |
| Comparative | 1 | 10.5 | <10 | — | — | B | B | B | D | D | D |
| Examples | 2 | 10.5 | <10 | — | — | D | D | D | C | C | C |
| | 3 | 10.5 | <10 | — | — | D | C | D | C | D | C |
| | 4 | 10.5 | <10 | — | — | D | D | D | B | B | B |
| | 5 | 12.5 | <10 | — | — | D | D | D | C | D | C |

As evident from Tables 1-1 and 1-2, it was confirmed that the cleaning liquid of the present invention was excellent in cleaning performance and corrosion prevention performance for a metal film containing cobalt. It was also confirmed that the cleaning liquid of the present invention was excellent in cleaning performance and corrosion prevention performance for a metal film containing copper and a metal film containing tungsten.

It was confirmed that when the mass ratio of the content of the amine compound Z to the content of the amine compound Y0 in the cleaning liquid was 2 to 100, the performances of the cleaning liquid were excellent in a well-balanced manner (see the results of, for instance, Examples 1 and 22 to 28).

It was confirmed that when two or more amine compounds Z were contained in the cleaning liquid, the effectiveness of the present invention was greater in excellence (see the results of, for instance, Examples 1 and 29 to 33).

It was confirmed that when the content of the amine compound Y0 in the cleaning liquid was more than 0.05 mass % and less than 5 mass % based on the total mass of the cleaning liquid, the performances of the cleaning liquid were excellent in a well-balanced manner (see the results of, for instance, Examples 1 and 22 to 28).

It was confirmed that when two or more amine compounds Y0 were contained in the cleaning liquid, the effectiveness of the present invention was greater in excellence (see the results of, for instance, Example 34).

It was confirmed that when one or both of the reducing sulfur compound and the hydroxycarboxylic acid were contained in the cleaning liquid, the effectiveness of the present invention was greater in excellence (see the results of, for instance, Examples 1 and 35 to 41).

It was confirmed that when the mass ratio of the content of the amine compound Y0 to the total content of the reducing sulfur compound and the hydroxycarboxylic acid in the cleaning liquid was 0.3 to 1.5, the effectiveness of the present invention was greater in excellence (see the results of, for instance, Example 41).

It was confirmed that when one or both (preferably both) of the azole compound and the biguanide compound were contained in the cleaning liquid, the effectiveness of the present invention was greater in excellence (see the results of, for instance, Examples 1 and 37 to 41).

It was confirmed that when the cleaning liquid contained the chelating agent (preferably adipic acid), the effectiveness of the present invention was greater in excellence (see the results of, for instance, Examples 1, 3, and 17).

In the above-described cleaning performance evaluation test, a wafer having a metal film made of copper or cobalt on its surface was subjected to a chemical mechanical polishing process, and then the surface of the polished wafer was subjected to a buffing process.

In the buffing process, a sample of each diluted cleaning liquid whose temperature was adjusted to room temperature (23° C.) was used as a buffing composition. The polishing apparatus used in the chemical mechanical polishing process above was used to perform the buffing process under the conditions of: a polishing pressure of 2.0 psi; a buffing composition feed rate of 0.28 mL/(minute·cm²); and a polishing time of 60 seconds.

Thereafter, the wafer having undergone the buffing process was cleaned for 30 seconds using a sample of each diluted cleaning liquid whose temperature was adjusted to room temperature (23° C.), and then dried.

With the polished surface of the obtained wafer, the cleaning performance of the cleaning liquid was evaluated according to the above-described evaluation test method. As a result, it was confirmed that the cleaning liquid had the same evaluation results as the evaluation results obtained from the cleaning liquids of Examples described above.

What is claimed is:

1. A cleaning liquid for a semiconductor substrate having undergone a chemical mechanical polishing process, the cleaning liquid comprising:
an amine compound Y0 that is at least one selected from the group consisting of: a compound Y1 represented by a general formula (Y1); and a compound Y2 having a 1,4-butanediamine skeleton,
wherein the cleaning liquid has a pH of 8.0 to 11.0, 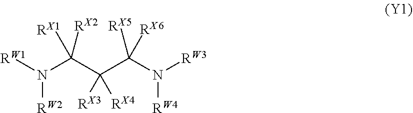
where R^{W1} to R^{W4} and R^{X1} to R^{X6} each independently represent a hydrogen atom or a hydrocarbon group that may have a substituent;
R^{W1} and R^{W2} may be bonded to R^{X1} to R^{X6} to form a ring;
R^{W3} and R^{W4} may be bonded to R^{X1} to R^{X6} to form a ring;
two groups selected from R^{X1} to R^{X6} may be bonded to each other to form a ring;
R^{W1} and R^{W2} may be bonded to each other to form a ring having, as its ring member atoms, only atoms selected from the group consisting of a carbon atom and a nitrogen atom; and
R^{W3} and R^{W4} may be bonded to each other to form a ring having, as its ring member atoms, only atoms selected from the group consisting of a carbon atom and a nitrogen atom,
provided that the general formula (Y1) satisfies at least one of a requirement A and a requirement B, the requirement A being that at least one of R^{W1} to R^{W4} represents a group other than a hydrogen atom, the requirement B being that at least two of R^{X1} to R^{X6} each represent a group other than a hydrogen atom.

2. The cleaning liquid according to claim 1, wherein the amine compound Y0 is at least one compound selected from the group consisting of 1,4-butandiamine, 2,2-dimethyl-1,3-propanediamine, N,N-dimethyl-1,3-propanediamine, N-methyl-1,3-diaminopropane, 3,3′-diamino-N-methyldipropylamine, 3,3′-diaminodipropylamine, N,N-diethyl-1,3-diaminopropane, N,N,2,2-tetramethyl-1,3-propanediamine, 3-(dibutylamino)propylamine, N,N,N′,N′-tetramethyl-1,3-diaminopropane, N,N′-bis(3-aminopropyl)ethylenediamine, 2,6,10-trimethyl-2,6,10-triazaundecan, N-(3-aminopropyl)diethanolamine, N-(3-aminopropyl)cyclohexylamine, 1,4-bis(3-aminopropyl)piperidine, 1-(3-aminopropyl)-2-methylpiperidine, 4-aminopiperidine, 4-amino-2,2,6,6-tetramethylpiperidine, 1,3-propanediamine-N,N,N′,N′-tetraacetic acid, 1-(3-aminopropyl)imidazole, N3-amine3-(2-aminoethylamino)propylamine, and N4-amine-N,N′-bis(3-aminopropyl)ethylenediamine.

3. The cleaning liquid according to claim 1, wherein the cleaning liquid further contains an amine compound Z different from the amine compound Y0.

4. The cleaning liquid according to claim 3, wherein a mass ratio of a content of the amine compound Z to a content of the amine compound Y0 is 2 to 100.

5. The cleaning liquid according to claim 4, wherein the amine compound Z comprises two or more amine compounds Z, and the cleaning liquid contains the two or more amine compounds Z.

6. The cleaning liquid according to claim 1, wherein a content of the amine compound Y0 is 1.0 to 30 mass % based on a total mass of components, excluding solvent, contained in the cleaning liquid.

7. The cleaning liquid according to claim 1, wherein the amine compound Y0 comprises two or more amine compounds Y0, and the cleaning liquid contains the two or more amine compounds Y0.

8. The cleaning liquid according to claim 1, wherein the cleaning liquid further contains an anticorrosive.

9. The cleaning liquid according to claim 8, wherein the anticorrosive includes a reducing agent.

10. The cleaning liquid according to claim 8, wherein the anticorrosive includes one or both of a reducing sulfur compound and a hydroxycarboxylic acid.

11. The cleaning liquid according to claim 10, wherein a mass ratio of a content of the amine compound Y0 to a total content of the reducing sulfur compound and the hydroxycarboxylic acid is 0.3 to 1.5.

12. The cleaning liquid according to claim 8, wherein the anticorrosive includes one or both of an azole compound and a biguanide compound.

13. The cleaning liquid according to claim 12, wherein the anticorrosive includes both the azole compound and the biguanide compound.

14. The cleaning liquid according to claim 1, wherein the semiconductor substrate has a metal film containing cobalt.

15. A method of cleaning a semiconductor substrate, the method comprising a step of applying the cleaning liquid according to claim 1 to the semiconductor substrate having undergone a chemical mechanical polishing process.

16. The cleaning liquid according to claim 2, wherein the cleaning liquid further contains an amine compound Z different from the amine compound Y0.

17. The cleaning liquid according to claim 16, wherein a mass ratio of a content of the amine compound Z to a content of the amine compound Y0 is 2 to 100.

18. The cleaning liquid according to claim 17, wherein the amine compound Z comprises two or more amine compounds Z, and the cleaning liquid contains the two or more amine compounds Z.

19. The cleaning liquid according to claim 2, wherein a content of the amine compound Y0 is 1.0 to 30 mass % based on a total mass of components, excluding solvent, contained in the cleaning liquid.

20. The cleaning liquid according to claim 2, wherein the amine compound Y0 comprises two or more amine compounds Y0, and the cleaning liquid contains the two or more amine compounds Y0.
